(19) United States
(12) Patent Application Publication
(10) Pub. No.: US 2010/0248419 A1
(43) Pub. Date: Sep. 30, 2010

(54) SOLAR CELL ABSORBER LAYER FORMED FROM EQUILIBRIUM PRECURSOR(S)

(76) Inventors: Jacob Woodruff, Mountain View, CA (US); Jeroen K.J. Van Duren, San Francisco, CA (US); Matthew R. Robinson, San Jose, CA (US); Brian M. Sager, Menlo Park, CA (US)

Correspondence Address: Director of IP, 5521 Hellyer Avenue, San Jose, CA, 95138, US

(21) Appl. No.: 12/706,709

(22) Filed: Feb. 16, 2010

Related U.S. Application Data
(60) Provisional application No. 61/152,727, filed on Feb. 15, 2009.

(51) Int. Cl. H01L 31/18

(52) U.S. Cl. 438/95; 257/E21.461; 257/E31.015

(57) ABSTRACT

Methods and devices are provided for forming an absorber layer. In one embodiment, a method is provided comprising of depositing a solution on a substrate to form a precursor layer. The solution comprises of at least one equilibrium and/or near equilibrium material. The precursor layer is processed in one or more steps to form a photovoltaic absorber layer. In one embodiment, the absorber layer may be created by processing the precursor layer into a solid film and then thermally reacting the solid film in an atmosphere containing at least an element of Group VIA of the Periodic Table to form the photovoltaic absorber layer. Optionally, the absorber layer may be processed by thermal reaction of the precursor layer in an atmosphere containing at least an element of Group VIA of the Periodic Table to form the photovoltaic absorber layer.

### CROSS-REFERENCE TO RELATED APPLICATIONS

This application claims priority to U.S. Provisional Application Ser. No. 61/152,727 filed Feb. 15, 2009, which is fully incorporated herein by reference for all purposes.

### FIELD OF THE INVENTION

This invention relates generally to photovoltaic devices, and more specifically, to use of equilibrium or near equilibrium precursors in forming photovoltaic devices.

### BACKGROUND OF THE INVENTION

Solar cells and solar modules convert sunlight into electricity. These electronic devices have been traditionally fabricated using silicon (Si) as a light-absorbing, semiconducting material in a relatively expensive production process. To make solar cells more economically viable, solar cell device architectures have been developed that can inexpensively make use of thin-film, preferably non-silicon, light-absorbing semiconductor materials such as copper-indium-gallium-selenide (CIGS).

A central challenge in cost-effectively constructing a large-area CIGS-based solar cell or module involves reducing processing costs and material costs. In known versions of CIGS solar cells, the CIGS absorber materials are typically deposited by a vacuum-based process over a rigid glass substrate. Typical CIGS deposition techniques include co-evaporation, sputtering, chemical vapor deposition, or the like. The nature of vacuum deposition processes requires equipment that is generally low throughput and expensive. Vacuum deposition processes are also typically carried out at high temperatures and for extended times. Furthermore, achieving precise stoichiometric composition over relatively large substrate areas desired in a manufacturing setting is difficult using traditional vacuum-based deposition processes. Traditional sputtering or co-evaporation techniques are limited to line-of-sight and limited-area sources, tending to result in poor surface coverage and non-uniform three-dimensional distribution of the elements. These non-uniformities can occur over the nano-, meso-, and/or macroscopic scales and alters the local stoichiometric ratios of the absorber layer, decreasing the potential power conversion efficiency of the complete cell or module. Additionally, vacuum deposition processes typically have a low material yield, often depositing material on non-targeted surfaces, and the vacuum process is labor intensive due to the frequent maintenance required

To address some of these issues, non-vacuum based techniques have been developed [Solar Energy, 2004, vol. 77, p 749]. Approaches like chemical bath deposition (CBD), electrodeposition, electroplating, spray pyrolysis or spray deposition, and solution-deposition of particles have been investigated. Chemical bath deposition, electrodeposition, electroplating, and some forms of spraying nucleate and grow a thin film directly from solution onto a substrate. A huge disadvantage of techniques that directly nucleate and grow a thin film from solution is the importance of the nature and cleanliness of the substrate surface to allow uniform nucleation and growth of high-quality multinary compound films. Incorporation of unwanted impurities from solution into the thin film during nucleation and growth typically affects the quality of the final multinary semiconductor absorber film disadvantageously resulting in lower solar cell efficiencies, either by incorporation of these impurities as electrical defects into the bulk crystals of the multinary absorber, or by preventing growth of a dense film of large crystals with low lattice defect concentrations, or by introducing unwanted contaminations onto the grain-boundaries of the crystals of the semiconductor thin film, all affecting the solar cell efficiency in a negative way.

Furthermore, these wet chemical deposition techniques typically require a more elaborate drying step to fully remove higher-boiling solvent from the dense as-deposited film, this in contrast to solvent removal from less-dense layers of as-deposited inks based on particles. For the latter, the solvent is removed before densification (of the particles into a densified film) which facilitates drying. Finally, the deposition step as used for CBD, electrodeposition, spraying, and the like, typically requires one or more subsequent high-temperature steps in a chalcogen-controlled atmosphere to improve the morphology of the as-deposited film in addition to the complication of growing these multinary films. Solution-deposition of nano- and/or sub-micron particles followed by converting these particles into a dense film circumvents most of the problems related to the direct nucleation and growth from solution onto a substrate.

Although some techniques may address cost and non-uniformity issues associated with vacuum deposition techniques, these known solution-deposition techniques of particles still use particles that are costly to synthesize into the desired shape and size or are difficult to handle in the powder form. Furthermore, the conversion of these precursor materials into the final thin-film absorber can create undesired changes in the uniformity of the resulting absorber. Due to the liquefying of one or more components of the precursor materials, there may be migration and/or bouldering that may occur, resulting in a much less uniform absorber than the uniformity of the precursor layer.

Due to the aforementioned issues, improved techniques are desired so that improved photovoltaic absorbers are formed. Improvements may be made to increase quality of CIGS/CIGSS manufacturing processes and decrease the cost associated with CIGS/CIGSS based solar devices. The decreased cost and increased production throughput should increase market penetration and commercial adoption of such products.

### SUMMARY OF THE INVENTION

Embodiments of the present invention address at least some of the drawbacks set forth above. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a method is provided comprising of depositing a solution on a substrate to form a precursor layer.

Optionally, the following may also be adapted for use with any of the embodiments disclosed herein. Processing comprises annealing with a ramp-rate of 1-5 C/sec, preferably over 5 C/sec, to a temperature of about 225 to 575° C. Optionally, processing comprises annealing with a ramp-rate of 1-5 C/sec, preferably over 5 C/sec, to a temperature of about 225 to 575° C. preferably for about 30 seconds to about 600 seconds to enhance conversion of precursor material, densification and/or alloying between Cu, In, and Ga in an atmosphere containing hydrogen gas, where the plateau temperature not necessarily is kept constant in time. Optionally, processing further comprises selenizing and/or sulfidizing this annealed layer with a ramp-rate of 1-5 C/sec, preferably over 5 C/sec, to a temperature of about 225 to 575 C for a time period of about 60 seconds to about 10 minutes in the appropriate VIA vapor, where the plateau temperature not necessarily is kept constant in time, to form the thin-film containing one or more chalcogenide compounds containing Cu, In, Ga, and Se. Optionally, processing comprises selenizing and/or sulfiziding without the separate annealing step in an atmosphere containing hydrogen gas, but may be densified and selenized in one step with a ramp-rate of 1-5 C/sec, preferably over 5 C/sec, to a temperature of 225 to 575 C for a time period of about 120 seconds to about 20 minutes in an atmosphere containing either H2Se or a mixture of H2 and Se vapor (or H2S or H2 and S vapor).

In one embodiment, the present invention minimizes thin spots in IB-IIIA-VIA absorber, and/or minimize and/or avoid exposure of back electrode (substrate) due to absence of IB-IIIA-VIA absorber material locally, and/or minimize thickness variation (decrease Ra and Rz), and/or improve compositional uniformity to increase overall efficiency. Although described herein for group IB-IIIA-VIA materials, it should be understood that the use of equilibrium material is applicable to other thin-film solar cell or semiconductor devices.

In this embodiment, the ink contains at least one type of particles where these particles in volume largely consist of the majority (by volume) high-liquefying phase in the single-phase or multi-phase film obtained after heat treatment. Typically, this heat treatment is non-reactive and provides for densification of the precursor. It should be noted that this phase does not liquefy or hardly liquefies during the heat treatment. Due to the minimal volume of liquid generated during heat treatment by this high-liquefying phase, worsening in thickness variations, and/or worsening of compositional variations upon heat treatment of the precursor material containing these particles are minimized, while the layer still partially or completely densifies. Example include but are not limited to Cu_{2.0}(In_{0.25}Ga_{0.75}), Cu₇₁Ga₂₉, Cu₉Ga₄, Cu(In,Ga)Se, Cu(In,Ga)S, and Cu(In,Ga)(S,Se).

It should be understood that for any of the embodiments herein may be adapted to include one or more of the following features. In one embodiment, a second type of particle having less than 82% In is used. Optionally, In2Se3 flake particles are used. Optionally, spherical In2O3 particles are used. Optionally, InOH3 is used. Optionally, the method further comprises using dispersant removal techniques. Optionally, Cu—In—Ga contain an oxygen content between about 6 to 8 wt %. Optionally, Cu—In—Ga contain an oxygen content between about 4 to 6 wt %. Optionally, Cu—In—Ga contain an oxygen content between about 1 to 4 wt %. Optionally, Cu—In—Ga contain an oxygen content between about 1 to 8 wt %. Optionally, reacting is a single step process. Optionally, reacting is a multi-step process. Optionally, reacting is a bilayer process. Optionally, reacting is a trilayer process. Optionally, the method further comprises depositing a group VIA on top of as-coated precursor. Optionally, the method includes depositing a group VIA on top of as-annealed precursor. Optionally, the precursor layer comprises of Cu—Ga, indium hydroxide, and elemental gallium. Optionally, the precursor layer comprises of Cu85Ga15, In(OH)3, and elemental gallium. Optionally, the precursor layer further comprises of copper nanoparticles and indium-gallium hydroxide. Optionally, the precursor layer further comprises copper-gallium and indium hydroxide without separate elemental gallium. Optionally, processing comprises annealing with a ramp-rate of 1-5 C/sec, preferably over 5 C/sec, to a temperature of about 225 to 550° C. Optionally, processing comprises annealing with a ramp-rate of 1-5 C/sec, preferably over 5 C/sec, to a temperature of about 225 to 550° C. preferably for about 30 seconds to about 600 seconds to enhance conversion of indium hydroxide, densification and/or alloying between Cu, In, and Ga in an atmosphere containing hydrogen gas, where the plateau temperature not necessarily is kept constant in time. Optionally, processing further comprise selenizing this annealed layer with a ramp-rate of over 5 C/sec, to a temperature of about 225 to 575 C for a time period of about 60 seconds to about 10 minutes in Se vapor in a non-vacuum atmosphere, where the plateau temperature not necessarily is kept constant in time, to form the thin-film containing one or more chalcogenide compounds containing Cu, In, Ga, and Se. Optionally, processing comprise selenizing without the separate annealing step in an atmosphere containing hydrogen gas, but may be densified and selenized in one step with a ramp-rate of over 5 C/sec, to a temperature of 225 to 575 C for a time period of about 120 seconds to about 20 minutes in an atmosphere containing either H2Se or a mixture of H2 and Se vapor in a non-vacuum pressure.

It should be understood that liquid can be created by e.g. liquefying of a single phase (or multiple phases), or by decomposition of a single solid phase into a solid phase and another liquid phase.

In terms of defects on the surface, there are differences between balling and dewetting. They are correlated but not 100%. Once can have a fully wetted back electrode surface, but still have big balls characterized by having a very thin layer of precursor in between the big balls. Same holds in reverse. One can have de-wetting, but not necessarily big balls (just in between the reasonably-sized islands the blanket/skin of precursor lacks at various locations).

Optionally, some embodiments always have individual islands (since this may have a multi-phase precursor film), but above a certain lateral island size and below a certain island height, the layer becomes very conformal (islands almost or completely touching). Above a certain island height (and therefore below a certain lateral island diameter), the island density drops, and the roughness increases. Too large a roughness, and too big balls, results in thin spots, and regions that are not fully homogenized to high-quality IB-IIIA-VIA, resulting in a lower efficiency.

Some embodiments provide examples of smooth, dense CIG films with H2-anneal starting with Cu+In+Ga (in a Ga/III range of 0.20-0.30; ink does not contain NaF). Optionally, some embodiments provide examples of smooth, dense CIG films starting with Cu—Ga+In, possibly Cu—Ga+In2O3, maybe even Cu—Ga+In(OH)2 (latter three inks may optionally contain NaF). Furthermore, reasonably smooth CIG can be obtained for mixture of Cu11In9+Ga—Na.

Optionally, some embodiments may use a layer (on top of the back electrode such as the Mo layer) to improve wetting (such as but not limited to Te, or an ultrathin layer containing at least one of the following elements: Cu, In, and/or Ga) to prevent the balling.

Optionally, some embodiments may use a lower temperature (e.g. APGD-H2-anneal) to minimize balling during H2-anneal (or in general: optimizing H2-anneal conditions to minimize balling, combined with optimizing particle size).

Optionally, some embodiments may use other annealing techniques (e.g. laser anneal) to minimize balling.

Optionally, some embodiments may use other chemical reduction steps (e.g. wet chemical, using solder flux).

Optionally, some embodiments may use a combination of chalcogenides with metallic (alloy) particles where one gets really smooth CIGSe films. So, a hybrid of chalcogenide and metallic particles (w/wo an intermediate step of H2-anneal or w/wo additional solder flux).

Optionally, some embodiments may use smooth films starting from binary selenides.

Optionally, some embodiments may use an H2-anneal Cu11In9 (or other Cu—In—Ga alloys) followed by deposition (vacuum, plating) of a Cu—Ga layer on top.

Optionally, some embodiments may use a use dispersant removal to minimize balling.

Optionally in this embodiment of the present invention, the ink contains at least one type of particles where these particles in volume largely consist of the majority (by volume) high-melting phase in the single-phase or multi-phase film obtained after heat treatment. Optionally, these particles provide at least 10 wt.-% of the majority high-melting phase in the film after heat treatment, optionally over 50 wt.-% of the majority high-melting phase, even more optionally over 75 wt.-% of the majority high-melting phase. Optionally, these particles provide at least 20 wt.-% of the majority high-melting phase in the film after heat treatment, optionally over 30 wt.-% of the majority high-melting phase, even more optionally over 40 wt.-% of the majority high-melting phase. These particles should be smaller in at least one dimension than the average thickness of the film after heat treatment, optionally 75% smaller in at least one dimension than the average thickness of the film after heat treatment, even more optionally in at least one dimension smaller than 50% of the average thickness of the film after heat treatment. The smaller the particle the more uniformly distributed this phase is in the final film. It should be noted that in some embodiments, this phase does not liquefy or hardly liquefies during the heat treatment. Due to the minimal volume of liquid generated during heat treatment by this high-melting phase, worsening in thickness variations, and/or worsening of compositional variations upon heat treatment of the precursor material containing these particles are minimized, while the layer still partially or completely densifies. Examples are Cu(In,Ga), with Cu/III>0.60, and 0.50>Ga/III>1.00, Cu(In,Ga)Se, Cu(In,Ga)S, and Cu(In,Ga)(S,Se).

Basically, a high-liquifying phase material is used to AVOID the uncontrolled nucleation and wetting challenges. The high-temperature liquefying phase material

(A) In one embodiment, the density (number/m²) of as-deposited high-melting phase containing particles is roughly equal to number of discrete high-melting phase islands/balls/domains after heat treatment (e.g. for case where one only adds a low concentration of high-melting phase containing particles).

(B) In another embodiment, the density (number/m²) of as-deposited high-melting phase containing particles is roughly equal to the number of discrete high-melting phase islands/balls/domains after heat treatment (e.g. for case where one add as much high-melting phase containing particles as the targeted film composition allows).

In some systems, the amount of equilibrium material used in terms of total amount of group IB material in the precursor is about 10-50% by weight of the IB material in the precursor layer after anneal. In one embodiment, the Ra is in the range of about 0.0744 to 0.138. In one embodiment, the Rz is in the range of about 2.2005 to 3.4006. The Ra is about 2× to 4× smoother than material that is formed without the use of equilibrium particles. The Rz is about 1.5× to 2.5× smoother. These roughness values may be used as a proxy in some embodiments for uniformity.

In addition to uniformity, the use of equilibrium particles may also resist the loss of Ga into the substrate or back contact layer during processing.

In another embodiment of the present invention, a method is provided comprising: creating a plurality of nucleation locations on a substrate, the nucleation point formed from a plurality of particles formed from an indium poor equilibrium material; adding a group IIIA-based material to the nucleation points; processing the precursor layer in one or more steps to form a photovoltaic absorber layer.

In another embodiment of the present invention, a method is provided comprising: creating a plurality of nucleation locations on a substrate, the nucleation point formed from a plurality of non-liquefying particles, non-liquefying up to a first processing temperature used; adding a group IIIA-based material to the nucleation points; processing the precursor layer in one or more steps to form a photovoltaic absorber layer.

In another embodiment of the present invention, a method is provided comprising: depositing a non-liquefying precursor material, non-liquefying up to a maximum processing temperature used; adding a group IIIA-based material to the non-liquefying precursor material; processing the precursor layer in one or more steps to form a photovoltaic absorber layer.

In another embodiment of the present invention, a method is provided comprising: depositing a non-liquefying precursor material, non-liquefying up to a maximum liquefying temperature used; adding a group IIIA-based material to the non-liquefying precursor material; processing the precursor layer in one or more steps to form a photovoltaic absorber layer; wherein the non-liquefying precursor material comprises of a plurality of planar particles sized less than about 2 microns.

In another embodiment of the present invention, a method is provided comprising: depositing a non-liquefying precursor material, non-liquefying up to a maximum liquefying temperature used; adding a group IIIA-based material to the non-liquefying precursor material; processing the precursor layer in one or more steps to form a photovoltaic absorber layer; wherein the non-liquefying precursor material comprises of a plurality of planar particles sized less than about 1 micron.

In another embodiment of the present invention, a method is provided comprising: depositing a non-liquefying precursor material, non-liquefying up to a maximum liquefying temperature used; adding a group IIIA-based material to the non-liquefying precursor material; processing the precursor layer in one or more steps to form a photovoltaic absorber layer; wherein the non-liquefying precursor material comprises of a plurality of planar particles sized less than about 1.5 micron.

In another embodiment of the present invention, a method is provided comprising: depositing a first component to form a non-liquefying precursor material, non-liquefying up to a maximum liquefying temperature used; heating; depositing a second component to form a non-liquefying precursor material, non-liquefying up to a maximum liquefying temperature used; adding a group IIIA-based material to the non-liquefying precursor material; processing the precursor layer in one or more steps to form a photovoltaic absorber layer.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Cu/III has a ratio of around 2.25 or higher in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Cu/III has a ratio of around 2.0 or higher in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Cu/III has a ratio of around 1.39 or higher in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Ga/III has a ratio of around 0.9 or lower in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Ga/III has a ratio of around 0.75 or lower in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the Ga/III has a ratio of around 0.75 to around 0.9999 in the ternary material.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the material does not liquefy during processing at temperature up to 780 C and do not result in balling.

In another embodiment of the present invention, a method is provided comprising: depositing a solution on a substrate to form a precursor layer, the solution comprising: at least one Group Cu-IIIA-IIIA ternary material; processing the precursor layer in one or more steps to form a photovoltaic absorber layer, wherein the material does not liquefy during processing at temperature up to 500 C.

In another embodiment of the present invention, a method is provided comprising: depositing a solution on a substrate to form a precursor layer, the solution comprising: at least one Group Cu-IIIA material; processing the precursor layer in one or more steps to form a photovoltaic absorber layer, wherein the material does not liquefy during processing at temperature up to 500 C, wherein a low-liquefying temperature group IIIA material is used to liquefy and fill voids between the non-liquefying material.

In another embodiment of the present invention, a method is provided comprising: depositing a solution on a substrate to form a precursor layer, the solution comprising: at least one Group Cu-IIIA-IIIA precursor material that is within 10% of each stoichiometric to a final desired composition in the CIG precursor material; processing the precursor layer in one or more steps to form a photovoltaic absorber layer, wherein the material does not liquefy during processing at temperature up to 500 C, wherein a low-liquefying temperature group IIIA material is used to liquefy and fill voids between the non-liquefying material.

In another embodiment of the present invention, a method is provided comprising: depositing a solution on a substrate to form a precursor layer, the solution comprising: at least one Group Cu-IIIA-IIIA precursor material that is within 20% of each stoichiometric to a final desired composition in the CIG precursor material; processing the precursor layer in one or more steps to form a photovoltaic absorber layer, wherein the material does not liquefy during processing at temperature up to 500 C, wherein a low-liquefying temperature group IIIA material is used to liquefy and fill voids between the non-liquefying material.

In another embodiment of the present invention, a method is provided comprising: depositing a solution on a substrate to form a precursor layer, the solution comprising: at least one Group Cu-IIIA-IIIA ternary material, wherein the ternary is copper rich, gallium-rich, indium poor; processing the precursor layer in one or more steps to form a photovoltaic absorber layer.

In another embodiment of the present invention, a method is provided comprising: depositing a solution on a substrate to form a precursor layer, the solution comprising: at least one Group Cu-IIIA-IIIA ternary material, wherein more than 50% of the IIIA material in the final absorber comes from a non-ternary particle; processing the precursor layer in one or more steps to form a photovoltaic absorber layer.

In another embodiment of the present invention, a method is provided comprising: depositing a solution on a substrate to form a precursor layer, the solution comprising: at least one Group Cu-IIIA-IIIA non-liquefying ternary material, wherein indium oxide liquefies to densify the film, filing voids between the non-liquefying material; processing the precursor layer in one or more steps to form a photovoltaic absorber layer.

In another embodiment of the present invention, a method is provided comprising: depositing a solution on a substrate to form a precursor layer, the solution comprising: at least one Group IIIA binary allow wherein the indium is less than 40 at. %; processing the precursor layer in one or more steps to form a photovoltaic absorber layer.

In another embodiment of the present invention, a method is provided comprising: depositing a solution on a substrate to form a precursor layer, the solution comprising: at least one Group IIIA binary allow wherein the indium alloy is In2O3 or In2Se3; processing the precursor layer in one or more steps to form a photovoltaic absorber layer.

A further understanding of the nature and advantages of the invention will become apparent by reference to the remaining portions of the specification and drawings.

### BRIEF DESCRIPTION OF THE DRAWINGS

FIGS. 1A-1D are schematic cross-sectional diagrams illustrating fabrication of a film according to an embodiment of the present invention.

FIGS. 2A-2F show a series of cross-sectional views showing formation of various layers of materials according to one embodiment of the present invention.

FIGS. 3A-3C show various embodiments of the present invention.

FIGS. 4A-4C show various views of non-spherical particles according to embodiments of the present invention.

FIGS. 5A-5C show the formation of a semiconductor layer from a precursor layer comprised of spherical and non-spherical particles.

FIGS. 6-8 show ternary phase diagrams according to embodiments of the present invention.

FIG. 9 shows a side cross-sectional view of a solar cell according to one embodiment of the present invention.

FIGS. 10A-10B shows side cross-sectional views of material for use in forming solar cells according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

“Salt” or “salts” means an acid where the proton (hydrogen cation) involved in acid-base chemistry is replaced with one or more metal cations. Metal hydroxides are not salts.

### Photovoltaic Device Chemistry

The solid particles for use with the present invention may be used with a variety of different chemistries to arrive at a desired semiconductor film. Although not limited to the following, an active layer for a photovoltaic device may be fabricated by formulating an ink of spherical and/or non-spherical particles each containing at least one element from groups IB, IIIA and/or VIA, coating a substrate with the ink to form a precursor layer, and heating the precursor layer to form a dense film. By way of non-limiting example, the particles themselves may be elemental particles or alloy particles. In some embodiments, the precursor layer forms the desired group IB-IIIA-VIA compound in a one step process. In other embodiments, a two step process is used wherein a dense film is formed and then further processed in a suitable atmosphere to form the desired group IB-IIIA-VIA compound. It should be understood that chemical reduction of the precursor layer may not be needed in some embodiments, particularly if the precursor materials are oxygen-free or substantially oxygen-free. Thus, a first heating step of two sequential heating steps may optionally be skipped if the particles are processed air-free and are oxygen-free. The resulting group IB-IIIA-VIA compound for either a one step or a two step process may be a mixture of compounds of Cu, In, Ga and selenium (Se) and/or sulfur S of the form Cu_{z}In₍₁₋ₓ₎GaₓS_{(2+w)(1-y)}Se_{(2+w)y}, where 0.5≦z≦1.5, 0≦x≦1, 0≦y≦1, and −0.2≦w≦0.5. Optionally, the resulting group IA-IB-IIIA-VIA thin-film may be a mixture of compounds of Cu, Na, In, Ga, and selenium (Se) and/or sulfur S of the form Cu_{z(u)}Na_{z(1-u)}In₍₁₋ₓ₎GaₓS_{(2+w)(1-y)}Se_{(z+w)y}, where 0.5≦z≦1.5, 0.5≦u≦1.0, 0≦x≦1, 0≦y≦1, and −0.2≦w≦0.5.

It should also be understood that group IB, IIIA, and VIA elements other than Cu, In, Ga, Se, and S may be included in the description of the IB-IIIA-VIA materials described herein, and that the use of a hyphen (“-” e.g., in Cu—Se or Cu—In—Se) does not indicate a compound, but rather indicates a coexisting mixture of the elements joined by the hyphen. It is also understood that group IB is sometimes referred to as group 11 (Cu, Au, Ag, etc. . . . ), group IIIA is sometimes referred to as group 13 and group VIA is sometimes referred to as group 16. Furthermore, elements of group VIA (16) are sometimes referred to as chalcogens. Where several elements can be combined with or substituted for each other, such as In and Ga, or Se, and S, in embodiments of the present invention, it is not uncommon in this art to include in a set of parentheses those elements that can be combined or interchanged, such as (In, Ga) or (Se, S). The descriptions in this specification sometimes use this convenience. Finally, also for convenience, the elements are discussed with their commonly accepted chemical symbols. Group IB elements suitable for use in the method of this invention include copper (Cu), silver (Ag), and gold (Au). Preferably the group IB element is copper (Cu). Group IIIA elements suitable for use in the method of this invention include gallium (Ga), indium (In), aluminum (Al), and thallium (Tl). Preferably the group IIIA element is gallium (Ga) and/or indium (In). Group VIA elements of interest include selenium (Se), sulfur (S), and tellurium (Te), and preferably the group VIA element is either Se and/or S. It should be understood that mixtures such as, but not limited to, alloys, solid solutions, and compounds of any of the above can also be used. The shapes of the solid particles may be any of those described herein.

Forming a Film from Particle Precursors

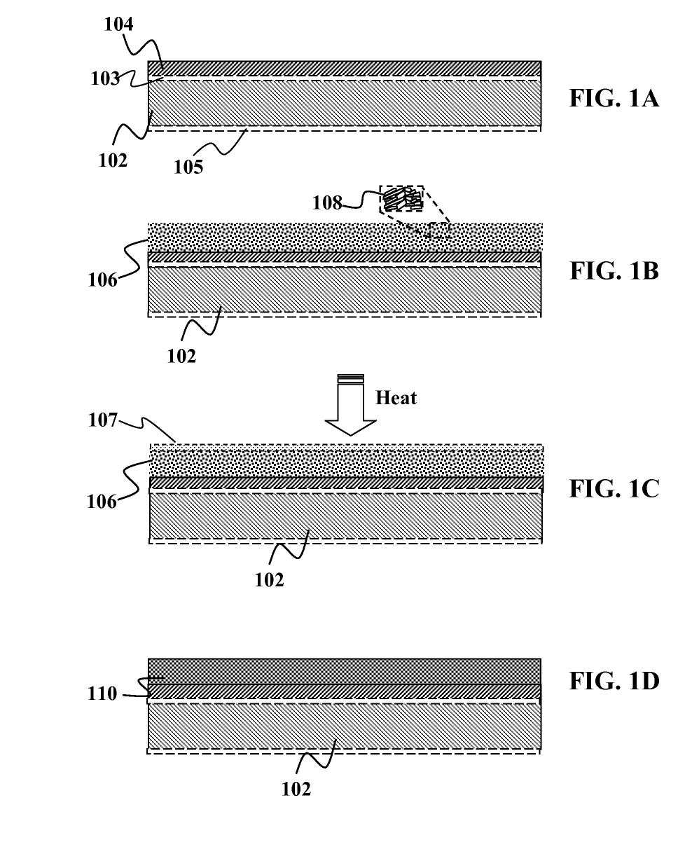

Referring now to FIGS. 1A-1D, one method of forming a semiconductor film from particles of precursor materials according to the present invention will now be described. It should be understood that the present embodiment uses non-vacuum techniques to form the semiconductor film. Other embodiments of the invention, however, may optionally form the film under a vacuum environment, and the use of solid particles (non-spherical and/or spherical) is not limited to only non-vacuum deposition or coating techniques. Optionally, some embodiments may combine both vacuum and non-vacuum techniques.

As seen in FIG. 1A, a substrate 102 is provided on which the precursor layer 106 (see FIG. 1B) will be formed. By way of non-limiting example, the substrate 102 may be made of a metal such as stainless steel or aluminum. In other embodiments, metals such as, but not limited to, copper, steel, coated aluminum, molybdenum, titanium, tin, metallized plastic films, or combinations of the foregoing may be used as the substrate 102. Alternative substrates include but are not limited to ceramics, glasses, and the like. Any of these substrates may be in the form of foils, sheets, rolls, the like, or combinations thereof. Depending on the conditions of the surface, and material of the substrate, it may be useful to clean and/or smoothen the substrate surface. Furthermore, depending on the material of the substrate 102, it may be useful to coat a surface of the substrate 102 with a contact layer 104 to promote electrical contact between the substrate 102 and the absorber layer that is to be formed on it, and/or to limit reactivity of the substrate 102 in subsequent steps, and/or to promote higher quality absorber growth. As a non-limiting example, when the substrate 102 is made of aluminum, the contact layer 104 may be but is not limited to a single or multiple layer(s) of molybdenum (Mo), tungsten (W), tantalum (Ta), binary and/or multinary alloys of Mo, W, and/or Ta, with or without the incorporation of a IA element like sodium, and/or oxygen, and/or nitrogen. Some embodiment may include a contact layer 104 comprised of a molybdenium-IA material such as but not limited to Na—Mo, Na—F—Mo, or the like deposited using a vacuum or non-vacuum technique. For the purposes of the present discussion, the contact layer 104 may be regarded as being part of the substrate. As such, any discussion of forming or disposing a material or layer of material on the substrate 102 includes disposing or forming such material or layer on the contact layer 104, if one is used. Optionally, other layers of materials may also be used with the contact layer 104 for insulation or other purposes and still considered part of the substrate 102. It should be understood that the contact layer 104 may comprise of more than one type or more than one discrete layer of material. Optionally, some embodiments may use any one and/or combinations of the following for the contact layer: a copper, aluminum, chromium, molybdenum, tungsten, tantalum, vanadium, etc. and/or iron-cobalt alloys or nickel-vanadium alloys. Optionally, a diffusion barrier layer 103 (shown in phantom) may be included and layer 103 may be electrically conductive or electrically non-conductive. As non-limiting examples, the layer 103 may be composed of any of a variety of materials, including but not limited to chromium, vanadium, tungsten, or compounds such as nitrides (including tantalum nitride, tungsten nitride, titanium nitride, silicon nitride, zirconium nitride, and/or hafnium nitride), oxy-nitrides (including tantalum oxy nitride, tungsten oxy nitride, titanium oxy nitride, silicon oxy nitride, zirconium oxy nitride, and/or hafnium oxy nitride), oxides (including Al₂O₃ or SiO₂), carbides (including SiC), binary and/or multinary compounds of W, Ti, Mo, Cr, V, Ta, Hf, Zr, and/or Nb, with/without the addition of either oxygen and/or nitrogen into these elemental, binary and/or multinary compound layers, and/or any single or multiple combination of the foregoing. Optionally, a diffusion barrier layer 105 (shown in phantom) may be on the underside of substrate 102 and be comprised of a material such as but not limited to chromium, vanadium, tungsten, or compounds such as nitrides (including tantalum nitride, tungsten nitride, titanium nitride, silicon nitride, zirconium nitride, and/or hafnium nitride), oxides (including alumina, Al₂O₃, SiO₂, or similar oxides), carbides (including SiC), and/or any single or multiple combination of the foregoing. The layers 103 and/or 105 may be adapted for use with any of the embodiments described herein. The layer 105 may be the same or a different material from that of layer 103.

Referring now to FIG. 1B, a precursor layer 106 is formed over the substrate 102 by coating the substrate 102 with a dispersion such as but not limited to an ink. As one non-limiting example, the ink may be comprised of a carrier liquid mixed with particles such as but not limited to microflakes 108 and has a rheology that allows the ink to be solution-deposited over the substrate 102. In one embodiment, the present invention may use a single dry powder or a mixture of two or more dry powders mixed with the vehicle containing or not containing a dispersant, and sonicated before coating. Optionally, the inks may be already formulated as the precursor materials are formed in a RF thermal plasma-based size reduction chamber such that discussed in U.S. Pat. No. 5,486,675 fully incorporated herein by reference. Optionally, the inks may be already formulated. In the case of mixing a plurality of flake compositions, the product may be mixed from various sources. This mixing could be by sonication but other forms of mechanical agitation and/or a mill may also be used. The ink used to form the precursor layer 106 may contain non-spherical particles 108 such as but not limited to microflakes and/or nanoflakes. It should also be understood that the ink may optionally use both non-spherical and spherical particles in any of a variety of relative proportions.

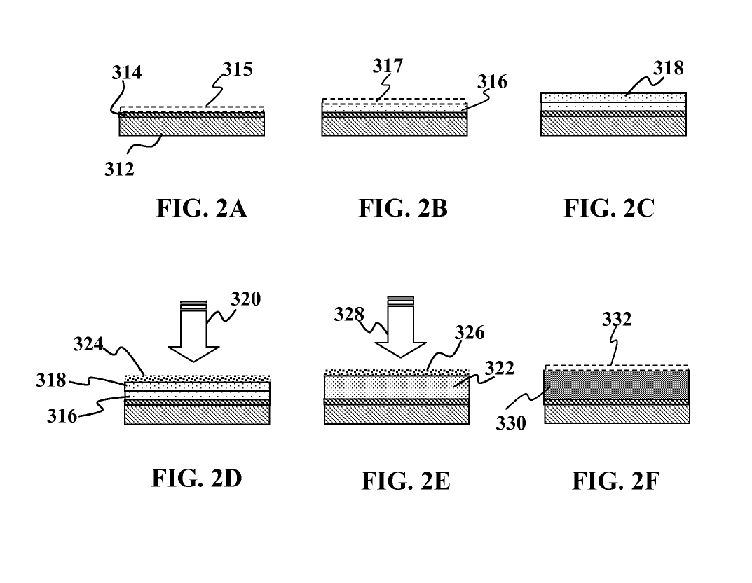

FIG. 1B includes a close-up view of the particles in the precursor layer 106, as seen in the enlarged image. Although not limited to the following, the particles may be microflakes 108 that have non-spherical shapes and are substantially planar on at least one side. A more detailed view of one embodiment of the microflakes 108 can be found in FIGS. 2A and 2B of U.S. patent application Ser. No. 11/362,266 filed Feb. 23, 2006 and fully incorporated herein by reference. Microflakes may be defined as particles having at least one substantially planar surface with a length and/or largest lateral dimension of about 500 nm or more and the particles have an aspect ratio of about 2 or more. In other embodiments, the microflake is a substantially planar structure with thickness of between about 10 and about 250 nm and lengths between about 500 nm and about 5 microns. It should be understood that in other embodiments of the invention, microflakes may have lengths of at least 1 micron or more. It should be understood that in other embodiments of the invention, microflakes may have lengths as large as 10 microns. Although not limited to the following, at least some of the solid group IIIA-particles may be processed into planar particles and adapted for use during solution deposition.

In one non-limiting example, the particles used to form the precursor layer 106 are elemental particles, i.e., having only a single atomic species. In one embodiment, the ink used for precursor layer 106 may contain particles comprising one or more group IB elements and particles comprising one or more different group MA elements. Preferably, the precursor layer 106 contains copper, indium and gallium. In another embodiment, the precursor layer 106 may be an oxygen-free layer containing copper, indium and gallium. Optionally, the ratio of elements in the precursor layer may be such that the layer, when processed, forms one or more phases where the phases contain one or more of the elements Cu, In, and Ga, and where the layer has the overall composition Cu_{z}InₓGa₁₋ₓ, where 0≦x≦1 and 0.5≦z≦1.5.

Optionally, some of the particles in the ink may be alloy particles. In one non-limiting example, the particles may be binary alloy particles such as but not limited to Cu—In, In—Ga, or Cu—Ga. Alternatively, the particles may be a binary alloy of group IB, MA elements, a binary alloy of Group IB, VIA elements, and/or a binary alloy of group IIIA, VIA elements. In other embodiments, the particles may be a ternary alloy of group IB, IIIA, and/or VIA elements. For example, the particles may be ternary alloy particles of any of the above elements such as but not limited to Cu—In—Ga. In other embodiments, the ink may contain particles that are a quaternary alloy of group IB, IIIA, and/or VIA elements. Some embodiments may have quaternary or multi-nary particles. It should also be understood that the source of group VIA material may be added as discussed in commonly assigned, co-pending U.S. patent application Ser. No. 11/243,522 (Attorney Docket No. NSL-046) filed on Feb. 23, 2006 and fully incorporated herein by reference.

Generally, an ink may be formed by dispersing any of the aforementioned particles (and/or other particles) in a vehicle containing a dispersant (e.g., a surfactant or polymer) along with (optionally) some combination of other components commonly used in making inks. In some embodiments of the present invention, the ink is formulated without a dispersant or other additive. The carrier liquid may be an aqueous (water-based) or non-aqueous (organic) solvent. Other components include, without limitation, dispersing agents, binders, emulsifiers, anti-foaming agents, dryers, solvents, fillers, extenders, thickening agents, film conditioners, anti-oxidants, flow and leveling agents, plasticizers, rheology modifiers, flame retarders, and preservatives. These components can be added in various combinations to improve the film quality and optimize the coating properties of the particle dispersion and/or improve the subsequent densification. Any of the ink formulations, dispersants, surfactants, or other additives described in U.S. patent application Ser. No. 12/175,945 filed Jul. 18, 2008 and fully incorporated herein by reference.

The precursor layer 106 from the dispersion may be formed on the substrate 102 by any of a variety of solution-based coating techniques including but not limited to wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink jet printing, jet deposition, spray deposition, and the like, as well as combinations of the above and/or related technologies. The foregoing may apply to any embodiments herein, regardless of particle size or shape.

Note that the method may be optimized by using, prior to, during, or after the solution deposition and/or (partial) densification of one or more of the precursor layers, any combination of (1) a layer to promote wetting and reduce balling to minimize overall roughness of the final IB-IIIA-VIA film, e.g. a layer of Te, or a back electrode deposited under optimized reactive sputter deposition conditions, (2) optimized particle shape, size, and composition of the precursor ink to minimize overall roughness of the final IB-IIIA-VIA film, (3) a dedicated dispersant removal step, e.g. a rinse step, laser annealing, or a UVO step, (4) lower-boiling and/or readily-decomposable dispersants and/or polymers in the ink, (5) addition of weak organic acids as used in e.g. solder flux to promote wetting, e.g. in the precursor ink or as a separate step, (6) addition of wet chemical reducing agents, e.g. in the precursor ink or as a separate step, (7) any (mixture of) chalcogen source(s) that can be solution-deposited, e.g. a Se or S nanopowder mixed into the precursor layers or deposited as a separate layer, (8) chalcogen (e.g., Se or S) evaporation, (9) a (mixture of) chalcogen-containing hydride gas(es) atmosphere (e.g. H₂Se, and/or H₂S) at pressures below, equal to, and/or above atmospheric pressure, (10) a steady-state and/or dynamic (mixture of) chalcogen vapor(s) atmosphere (e.g., Se, and/or S) at pressures below, equal to, and/or above atmospheric pressure, (11) an organo-selenium containing atmosphere, e.g. diethylselenide, at pressures below, equal to, and/or above atmospheric pressure, (12) an H₂ atmosphere at pressures below, equal to, and/or above atmospheric pressure, (13) another reducing atmosphere, e.g. CO, at pressures below, equal to, and/or above atmospheric pressure, (14) a wet chemical reduction step, (15) generation of a plasma to break the chemical bonds in the vapor(s) and/or gas(es) in the atmosphere to increase the reactivity of these species, at pressures below, equal to, and/or above atmospheric pressure, (16) a steady-state and/or dynamic atmosphere containing a sodium source, (e.g. Na—Se or Na—S), at pressures below, equal to, and/or above atmospheric pressure, (17) liquid deposition of a chalcogen source, e.g. as molten Se and/or S, (18) exposure to air, (19) exposure to a substantially moisture-free atmosphere, (20) exposure to a substantially O₂-free atmosphere, (21) exposure to an atmosphere based on an inert gas like N₂ and/or Ar, (22) exposure to an atmosphere with a controlled concentration of H₂O and/or O₂, (23) deposition of one or more IB, IIIA, VIA, and IA elements via vacuum deposition, a (24) heat treatment, and (25) a rinse step.

Referring now to FIG. 1C, the precursor layer 106 of particles may then be processed in a suitable atmosphere to form a film. In one embodiment, this processing involves heating the precursor layer 106 to a temperature sufficient to convert the ink to a film (conversion of as-deposited ink to a film; note that solvent and possibly dispersant have been removed by drying or other removal technique). The heating may involve various thermal processing techniques such as pulsed thermal processing, exposure to laser beams, heating via IR lamps, and/or similar or related processes, e.g. based on conduction and/or convection heating. Although not limited to the following, the temperature during heating may be between about 375° C. and about 525° C. (a safe temperature range for processing on aluminum foil or high-temperature-compatible polymer substrates). The processing may occur at various temperatures in this range, such as but not limited to a constant temperature of 450° C. In other embodiments, the temperature may be between about 400° C. and about 600° C. at the level of the precursor layer, but cooler at the substrate. In other embodiments, the temperature may be between about 500° C. and about 600° C. at the level of the precursor layer.

The atmosphere associated with the annealing step in FIG. 1C may also be varied. In one embodiment, the suitable atmosphere comprises an atmosphere containing more than about 10% hydrogen. In another embodiment the suitable atmosphere comprises a carbon monoxide atmosphere. However, in other embodiments where very low or no amounts of oxygen are found in the particles, the suitable atmosphere may be a nitrogen atmosphere, an argon atmosphere, or an atmosphere having less than about 10% hydrogen, e.g. forming gas. These other atmospheres may be advantageous to enable and improve material handling during production.

Referring now to FIG. 1D, the precursor layer 106 processed in FIG. 1C will form a film 110. The film 110 may actually have a reduced thickness compared to the thickness of the wet precursor layer 106 since the carrier liquid and other materials have been removed during processing. In one non-limiting embodiment, the film 110 may have a thickness in the range of about 0.5 microns to about 2.5 microns. In other embodiments, the thickness of film 110 may be between about 1.5 microns and about 2.25 microns. In one embodiment, the resulting dense film 110 may be substantially void free. In some embodiments, the dense film 110 has a void volume of about 5% or less. In other embodiments, the void volume is about 10% or less. In another embodiment, the void volume is about 20% or less. In still other embodiments, the void volume is about 24% or less. In still other embodiments, the void volume is about 30% or less. The processing of the precursor layer 106 will fuse the particles together and in most instances, remove void space and thus reduce the thickness of the resulting dense film.

Depending on the type of materials used to form the film 110, the film 110 may be suitable for use as an absorber layer or be further processed to become an absorber layer. More specifically, the film 110 may be a film as a result of a one step process, or for use in another subsequent one step process making it a two step process, or for use in a multi-step process. In a one step process, the film 110 is formed to include group IB-IIIA-VIA compounds and the film 110 may be an absorber film suitable for use in a photovoltaic device. In a two step process, the film 110 may be a solid, annealed, and/or densified film that will have further processing to be suitable for use as an absorber film for use in a photovoltaic device. As a non-limiting example, the film 110 in a two step process may not contain any and/or sufficient amounts of a group VIA element to function as an absorber layer. Adding a group VIA element or other material may be the second step of the two-step process. Either a mixture of two or more VIA elements can be used, or a third step can be added with another VIA element as used in the second step. A variety of methods of adding that material include printing of group VIA element, using VIA element vapor, and/or other techniques. It should also be understood that in a two step process, the process atmospheres may be different. By way of non-limiting example, one atmosphere may optionally be a group VIA-based atmosphere. As another non-limiting example, one atmosphere may be an inert atmosphere as described herein. Other processing steps as used in a multi-step process may be a wet chemical surface treatment to improve the IB-IIIA-VIA thin-film surface and/or grain boundaries, and/or an additional rapid thermal heating to improve bulk and/or surface properties of the IB-IIIA-VIA thin-film.

### Particle Shapes

It should be understood that any of solid particles as discussed herein may be used in spherical and/or non-spherical particle shapes. FIG. 1A shows that the particles may all be non-spherical, planar flake particles. By way of example and not limitation, it should be understood that the solid Group IIIA-based particles may be particles of various shapes used with any of the combinations shown below in Table III. Flakes may be considered to be one type of non-spherical particles.

TABLE III

| | Spherical | Non-Spherical | Flake | Nanoglobules |
|---|---|---|---|---|
| Spherical | Spherical | Non-spherical + | Flake + | Nanoglobules + |
| | | Spherical | Spherical | Spherical |
| Non-Spherical | Spherical + | Non-spherical | Flake + | Nanoglobules + |
| | Non-spherical | | Non-spherical | Non-spherical |
| Flake | Spherical + | Non-spherical + | Flake | Nanoglobules + |
| | Flake | Flake | | Flake |
| Nanoglobules | Spherical + | Non-spherical + | Flake + | Nanoglobules |
| | Nanoglobules | Nanoglobules | Nanoglobules | |
| Spherical + | Spherical + | Spherical + | Spherical + | Spherical + |
| Non-spherical | Non-spherical | Non-spherical | Non-spherical + | Non-spherical + |
| | | | Flake | Nanoglobules |
| Spherical + | Spherical + | Spherical + | Spherical + | Spherical + |
| Flake | Flake | Flake + | Flake | Flake + |
| | | Non-spherical | | Nanoglobules |
| Spherical + | Spherical + | Spherical + | Spherical + | Spherical + |
| Nanoglobules | Nanoglobules | Nanoglobules + | Nanoglobules + | Nanoglobules |
| | | Non-spherical | Flake | |
| Flake + | Flake + | Flake + | Flake + | Flake + |
| Nonspherical | Nonspherical + | Nonspherical | Nonspherical | Nonspherical + |
| | Spherical | | | Nanoglobules |
| Flake + | Flake + | Flake + | Flake + | Flake + |
| Nanoglobules | Nanoglobules + | Nanoglobules + | Nanoglobules | Nanoglobules |
| | Spherical | Non-spherical | | |
| Non-spherical + | Non-spherical + | Non-spherical + | Non-spherical + | Non-spherical + |
| Nanoglobules | Nanoglobules + | Nanoglobules | Nanoglobules + | Nanoglobules |
| | Spherical | | Flake | |

It should be understood that the salt particles described herein may be size reduced to be spherical and/or non-spherical in shape and is not limited to any one particular configuration.

### Additional Sodium

Referring now to FIGS. 2A-2F, it should be understood that even with solid group IIIA-based particles, more sodium may be desired to provide improved performance. This embodiment of the invention shows that layers of material may be deposited above and/or below the precursor layer. Some layers may be deposited after the precursor layer has been processed. Although not limited to the following, these layers may provide one technique for adding additional sodium.

Referring now to FIG. 2A, the absorber layer may be formed on a substrate 312, as shown in FIG. 2A. A surface of the substrate 312 may be coated with a contact layer 314 to promote electrical contact between the substrate 312 and the absorber layer that is to be formed on it. By way of example, a metal substrate 312 may be coated with a contact layer 314 of molybdenum. As discussed herein, forming or disposing a material or layer of material on the substrate 312 includes disposing or forming such material or layer on the contact layer 314, if one is used. Optionally, it should also be understood that a layer 315 may also be formed on top of contact layer 314 and/or directly on substrate 312. This layer may be solution-deposited (e.g. coated, printed, or plated), evaporated, and/or deposited using vacuum based techniques. Although not limited to the following, the layer 315 may have a thickness less than that of the precursor layer 316. In one non-limiting example, the layer may be between about 1 nm to about 100 nm in thickness. The layer 315 may be comprised of various materials including but not limited to at least one of the following: a group IB element, a group IIIA element, a group VIA element, a group IA element (new style: group 1), a binary and/or multinary alloy of any of the preceding elements, a solid solution of any of the preceding elements, copper, indium, gallium, selenium, copper indium, copper gallium, indium gallium, sodium, a sodium compound, sodium fluoride, sodium indium sulfide, copper selenide, copper sulfide, indium selenide, indium sulfide, gallium selenide, gallium sulfide, copper indium selenide, copper indium sulfide, copper gallium selenide, copper gallium sulfide, indium gallium selenide, indium gallium sulfide, copper indium gallium selenide, and/or copper indium gallium sulfide.

As shown in FIG. 2B, a precursor layer 316 is formed on the substrate. The precursor layer 316 contains one or more group IB elements and one or more group IIIA elements. Preferably, the one or more group IB elements include copper. The one or more group IIIA elements may include indium and/or gallium. The precursor layer may be formed using any of the techniques described above. In one embodiment, the precursor layer contains no oxygen other than those unavoidably present as impurities or incidentally present in components of the film other than the flakes themselves. Although the precursor layer 316 is preferably formed using non-vacuum methods, it should be understood that it may optionally be formed by other means, such as evaporation, sputtering, chemical vapor deposition, physical vapor deposition, atomic layer deposition, ALD, electro-plating, electro-deposition, etc. By way of example, the precursor layer 316 may be an oxygen-free compound containing copper, indium and gallium. In one embodiment, the non-vacuum system operates at pressures above about 3.2 kPa (24 Torr). Optionally, it should also be understood that a layer 317 may also be formed on top of precursor layer 316. It should be understood that the stack may have both layers 315 and 317, only one of the layers, or none of the layers. Although not limited to the following, the layer 317 may have a thickness less than that of the precursor layer 316. In one non-limiting example, the layer 317 may be between about 1 to about 100 nm in thickness. The layer 317 may be comprised of various materials including but not limited to at least one of the following: a group IB element, a group IIIA element, a group VIA element, a group IA element (new style: group 1), a binary and/or multinary alloy of any of the preceding elements, a solid solution of any of the preceding elements, copper, indium, gallium, selenium, copper indium, copper gallium, indium gallium, sodium, a sodium compound, sodium fluoride, sodium indium sulfide, copper selenide, copper sulfide, indium selenide, indium sulfide, gallium selenide, gallium sulfide, copper indium selenide, copper indium sulfide, copper gallium selenide, copper gallium sulfide, indium gallium selenide, indium gallium sulfide, copper indium gallium selenide, and/or copper indium gallium sulfide.

Referring now to FIG. 2D, heat 320 is applied to densify the first precursor layer 316 into a group IB-IIIA compound film 322. The heat 320 may be supplied in a rapid thermal annealing process, e.g., as described above. As a non-limiting example, the substrate 312 and precursor layer(s) 316 may be heated from an ambient temperature to a plateau temperature range of between about 200° C. and about 600° C. The temperature may be maintained in the plateau range for a period of time ranging between about a fraction of a second to about 60 minutes, and subsequently reduced. The heat turns the precursor layer into a film 322. Optionally, this may be a dense, metallic film as shown in FIG. 2D. The heating may remove voids and create a denser film than the precursor layer. In other embodiments, where the precursor layer is already dense, there may be little to no densification.

Optionally, as shown in FIG. 2E, a layer 326 containing an additional chalcogen source, and/or an atmosphere containing a chalcogen source, may be applied to layer 322. Heat 328 may optionally be applied to layer 322 and the layer 326 and/or atmosphere containing the chalcogen source to heat them to a temperature sufficient to liquefy the chalcogen source and to react the chalcogen source with the group IB element and group IIIA elements in the precursor layer 322. The heat 328 may be applied in a rapid thermal annealing process, e.g., as described above. The reaction of the chalcogen source with the group IB and IIIA elements forms a compound film 330 of a group IB-IIIA-chalcogenide compound as shown in FIG. 2F. Preferably, the group IB-IIIA-chalcogenide compound is of the form Cu_{z}In₁₋ₓGaₓSe_{2(1-y)}S_{2y}, where 0≦x≦1, 0≦y≦1, and 0.5≦y≦1.5. Although not limited to the following, the compound film 330 may be thicker than the film 322 due to the reaction with group VIA elements.

Referring now to FIGS. 2A-2F, it should be understood that sodium may also be used with the precursor material to improve the qualities of the resulting film. This may be particularly useful in the situation where solid Group IIIA particles are formed without using a sodium based material and additional sodium is desired. In a first method, as discussed in regards to FIGS. 2A and 2B, one or more layers of a sodium containing material may be formed above and/or below the precursor layer 316. The formation may occur by solution coating and/or other techniques such as but not limited to sputtering, evaporation, CBD, electroplating, sol-gel based coating, spray coating, chemical vapor deposition (CVD), physical vapor deposition (PVD), atomic layer deposition (ALD), and the like.

Optionally, in a second method, sodium may also be introduced into the stack by sodium doping the flakes and/or particles in the precursor layer 316. As a nonlimiting example, the flakes and/or other particles in the precursor layer 316 may be a sodium containing material such as, but not limited to, Cu—Na, In—Na, Ga—Na, Cu—In—Na, Cu—Ga—Na, In—Ga—Na, Na—Se, Cu—Se—Na, In—Se—Na, Ga—Se—Na, Cu—In—Se—Na, Cu—Ga—Se—Na, In—Ga—Se—Na, Cu—In—Ga—Se—Na, Na—S, Cu—In—Ga—Na, Cu—S—Na, In—S—Na, Ga—S—Na, Cu—In—S—Na, Cu—Ga—S—Na, In—Ga—S—Na, and/or Cu—In—Ga—S—Na. In one embodiment of the present invention, the amount of sodium in the flakes and/or other particles may be about 1 at. % or less. In another embodiment, the amount of sodium may be about 0.5 at. % or less. In yet another embodiment, the amount of sodium may be about 0.1 at. % or less. It should be understood that the doped particles and/or flakes may be made by a variety of methods including milling feedstock material with the sodium containing material and/or elemental sodium.

Optionally, in a third method, sodium may be incorporated into the ink itself, regardless of the type of particle, nanoparticle, microflake, and/or nanoflakes dispersed in the ink. As a nonlimiting example, the ink may include flakes (Na doped or undoped) and a sodium compound with an organic counter-ion (such as but not limited to sodium acetate) and/or a sodium compound with an inorganic counter-ion (such as but not limited to sodium sulfide). It should be understood that sodium compounds added into the ink (as a separate compound), might be present as particles (e.g. nanoparticles), or dissolved and/or in (reverse) micelles. The sodium may be in “aggregate” form of the sodium compound (e.g. dispersed particles), and the “molecularly dissolved” form.

None of the three aforementioned methods are mutually exclusive and may be applied singly or in any single or multiple combination(s) to provide the desired amount of sodium to the stack containing the precursor material. Additionally, sodium and/or a sodium containing compound may also be added to the substrate (e.g. into the molybdenum target). Also, sodium-containing layers may be formed in between one or more precursor layers if multiple precursor layers (using the same or different materials) are used. It should also be understood that the source of the sodium is not limited to those materials previously listed. As a nonlimiting example, basically, any deprotonated alcohol where the proton is replaced by sodium, any deprotonated organic and inorganic acid, the sodium salt of the (deprotonated) acid, NaₓH_{y}Se_{z}SᵤTeᵥO_{w} where x, y, z, u, v, and w≧O, NaₓCu_{y}In_{z}GaᵤOᵥ where x, y, z, u, and v≧0 sodium hydroxide, sodium acetate, and the sodium salts of the following acids: butanoic acid, hexanoic acid, octanoic acid, decanoic acid, dodecanoic acid, tetradecanoic acid, hexadecanoic acid, 9-hexadecenoic acid, octadecanoic acid, 9-octadecenoic acid, 11-octadecenoic acid, 9,12-octadecadienoic acid, 9,12,15-octadecatrienoic acid, and/or 6,9,12-octadecatrienoic acid.

Optionally, as seen in FIG. 2F, it should also be understood that sodium and/or a sodium compound may be added to the processed chalcogenide film after the precursor layer has been densified or otherwise processed. This embodiment of the present invention thus modifies the film after formation of binary, and/or multinary chalcogenides, like CIGS. With sodium, electronic properties of the film improve, resulting in an increase of Voc and FF. A variety of sodium containing materials such as those listed above may be deposited as layer 332 onto the processed film and then annealed to treat the chalcogenide film.

Additionally, the sodium material may be combined with other elements that can provide a bandgap widening effect. Two elements which would achieve this include gallium and sulfur. The use of one or more of these elements, in addition to sodium, may further improve the quality of the absorber layer. The use of a sodium compound such as but not limited to Na₂S, NaInS₂, or the like provides both Na and S to the film and could be driven in with an anneal such as but not limited to an RTA step to provide a layer with a bandgap different from the bandgap of the unmodified CIGS layer or film.

### Hybrid Nucleation/Precursor Layer

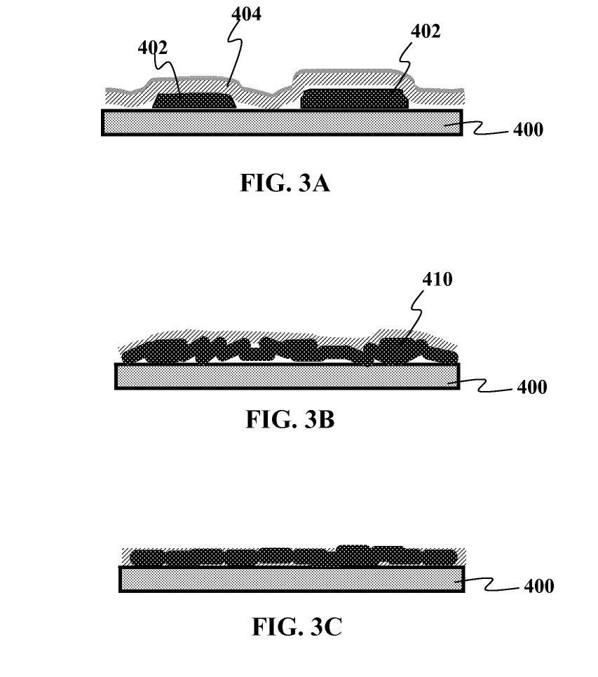

Referring now to FIGS. 3 to 5, a still further embodiment of the present invention will now be described. It should be understood that during processing of the precursor materials in one or more steps into the final semiconductor absorber, the precursor materials may be heated in one of these steps to a temperature wherein the material will become sufficiently liquid and/or active either by liquefying or phase transformation separation so as to reflow and reform. Thus, although the deposition of the precursor layer may result in a smooth, uniform precursor layer, the reflow and migration of materials during processing can result in a much different layer uniformity, roughness (smoothness), homogeneity, and a change in type, size, shape, orientation, composition, quality, and number of crystals within the layer. Even those compositions starting with solid particles without liquid precursor materials or liquid phases in the particles at or near deposition temperatures do not guarantee a resulting layer that is similar in smoothness and/or atomic uniformity as the deposited layer, due in part to the reflow and migration. Processing of the layer can occur in an inert atmosphere or in a reactive atmosphere. In some embodiments, for processes that anneal prior to reactive processing, this re-flow of the precursor material can occur during one or more annealing steps that may occur before reactive processing.

Referring now to FIG. 3A, this example shows that the equilibrium materials on the substrate 400 result from re-flow or material migration form a plurality of islands 402, some with a blanket 404 of residual material not incorporated into the equilibrium material covering some or all portion of the islands of equilibrium material. It should be understood that this embodiment of FIG. 3A does not start with the equilibrium material. The equilibrium material is subsequently formed during heating and where this equilibrium material forms on the substrate is not controlled or predetermined. To the extent that reflow or reorganization creates bouldering, mounding, or non-uniformity in the layer, such re-flow or reorganization creates non-uniformity that is less desired. Non-uniformity could also be expressed as differences in atomic composition laterally or other axis. By way of non-limiting example, the non-uniformity may be expressed in physical form as bare spots or thinned spots where material has flowed away from certain locations. In other embodiments, the non-uniformity may be in the form of boulders or mounds that rise above the surface or plane of the other materials in the layer. Without being limited to any particular theory, this non-uniform gathering of material can result in part due to the irregular growth of material during processing. This shows that in some processes, it is not possible to fully control where these islands of equilibrium material form and/or the subsequent size of the island formed since nucleation is less controllable. To minimize material non-uniformity that can occur during heating of the precursor material, it is desirable to implement some mechanism and/or process control to regulate how the material reflows or reorganizes during processing.

One embodiment of the present invention proposes the use of a layer that is simultaneously a nucleation layer and a precursor layer. In this nonlimiting example, the hybrid layer comprises of a portion that includes nucleation components that are pre-distributed or predetermined to maximize layer uniformity and minimize clumping, bouldering, or thinning of materials on the substrate. These nucleation components are optionally evenly distributed over the surface of the substrate to provide many nucleation points on the substrate. The uniform distribution may occur in a two dimensional (2D), lateral manner. Optionally, the uniform distribution may also include controlled layer thickness in the vertical direction for greater three dimensional (3D) uniformity. At one extreme, the layer may be a uniform layer without “particles” per se, with uniformity at the atomic or molecular level.

Optionally, the nucleation components are completely non-liquefying materials. Optionally, the nucleation components are such that only a minority portion will liquefy during processing, but the majority remains non-liquefying during processing. Optionally, the nucleation components are equilibrium materials. Optionally, the nucleation components are single or multiple combinations of the foregoing. Optionally, it should be understood that the nucleation components are configured to be particles of size and shape that maximizes the creation of more uniform layers.

In addition to the nucleation component, it should be understood that this embodiment of the hybrid nucleation/precursor layer also includes at least one additional material that is liquefying and will reflow during processing. This second material may be such that it flows sufficiently to fill a majority of voids. It may also be a material that may or may not be incorporated into the nucleation material. By way of non-limiting example, the particles in one embodiment are not large in vertical height than the thickness of the coated film or precursor layer. The size and density may be determined by the uniformity that can be tolerated. Ultimately, this could reduce to a thin film of nucleation material.

Intralayer nucleation results due to the incorporation of the nucleation material into the precursor layer that contains the nucleation material and at least a second or other material in the layer. Intralayer nucleation in this hybrid nucleation/precursor layer will allow the film to simultaneously densify into a thinner layer without the undesired material migration that may create bouldering or lateral composition nonuniformity if the densification process occurs with the uncontrolled formation of the equilibrium material. In some embodiment, the material may separate or exude liquid material.

In one nonlimiting example, the material for the hybrid nucleation/precursor layer is coated onto a substrate at about 1 micron thickness; the coating is heated to densify the coating and to reduce thickness to about 0.5 to 0.6 microns thickness; the densified coating is heated in one or more reactive atmospheres to form the final absorber layer which increases thickness about (3×) from the densified layer.

Referring now to FIG. 3B, in one embodiment of the present invention, using a final equilibrium composition or incorporating a component in the starting material 410 with near equilibrium composition that does not significantly reflow or generate liquid during processing provides greater control over the nucleation locations of the islands that form during processing of the precursor material at heated temperature. Thus, the equilibrium composition starting material provides morphology control from the resulting processed layers. Specifically, there is at least lateral, 2D uniformity control due in part to the even distribution of this equilibrium material over the substrate. If one introduces multiple locations where the equilibrium material is already located or pre-positioned on the substrate, the process will have less migration of material and random nucleation or growth. This can substantially increase material uniformity and reduce bouldering or mounding of material that may occur if random nucleation occurs. Thus, although there may still be some reduced level of material re-flow, the amount of movement is substantially reduced. Thus in some embodiments, the surface roughness may be determined in part by how smoothly and uniformity the non-liquefying precursor material is deposited on the substrate 400.

Referring now to FIG. 3C, it is shown that an even smoother and/or flatter distribution of non-liquefying precursor materials may create even smoother final semiconductor absorber layers due to the reduced starting roughness and the less chance of material moving and re-organizing. In one embodiment, the hybrid nucleation/precursor layer may have the majority of the nucleation material in contact with the substrate while the second type material is mostly in contact with the nucleation material and not directly in contact with the substrate. Optionally, the nucleation/precursor layer could be a continuous layer. In some instances, this creates embodiments wherein the backside of the layer is mostly nucleation material, while the second material is mostly on the topside of the layer. Optionally, the layer may have nucleation material even distributed vertically through the layer.

### Equilibrium Material

Referring now to the nucleation material used in the hybrid nucleation/precursor layer, it should be understood that one embodiment of this nucleation material comprises of an equilibrium material that will not incorporate or will not substantially incorporate any additional material into the equilibrium material during heating of the hybrid nucleation/precursor. Optionally, it will not separate or exude liquid material during processing. In this example, the present invention provides for a starting material wherein at least one portion of the starting material will be a ternary equilibrium composition that is the same as the equilibrium material after anneal. This equilibrium composition and at least a second material will be further processed in one or more steps to form the final semiconductor material. Such steps are typically, but not limited to, reactive steps. Optionally, the material is annealed and reacted in the same step.

In the present embodiment, the equilibrium material after annealing is a ternary compound. In one non-limiting example, the equilibrium composition for a ternary group IB-IIIA-IIIA material is any composition between the range of Cu₂In_{0.25}Ga_{0.75} to C_{2.25}In_{0.25}Ga_{0.75}. Optionally, other non-liquefying or substantially non-liquefying ternary equilibrium materials may be in the range from Cu₂(In₁₋ₓGaₓ) to Cu_{2.25}(In₁₋ₓGaₓ), wherein 0.5<x<1. As seen herein, this is a CIG material which will then be processed in a reactive step into the final absorber layer. This concept of using equilibrium composition material is not limited to CIG materials or other precursors for IB-IIIA-VIA absorber and can also apply to others such as but not limited to CZTS absorber materials.

As seen, this embodiment shows that the equilibrium material is typically an indium poor ternary material. In other embodiments, the equilibrium material may have other compositions. In the present case, the ternary is such that, because it is an equilibrium material, it will incorporate very little, if any, of the In or Ga into its composition. Optionally, there may be less than 1% change in the amount of any of the components of the ternary after anneal.

Optionally, it should be understood that in some embodiments, there is a prevalence of equilibrium material in the precursor layer. In one embodiment, over 50% of the material in the precursor layer comprise of the equilibrium material. Optionally, over 60% of the material in the precursor layer comprise of the equilibrium material. Optionally, over 70% of the material in the precursor layer comprise of the equilibrium material. Optionally, over 80% of the material in the precursor layer comprise of the equilibrium material. Optionally, less than 50% of the group IIIA material comes from the equilibrium material. Optionally, less than 45% of the group IIIA material comes from the equilibrium material. Optionally, less than 40% of the group IIIA material comes from the equilibrium material.

By using such a material, this configuration should have less material migration during the processing of the precursor layer at heated temperatures. In some embodiments, this ternary material will provide 2-dimensional or lateral gallium uniformity due in part to the majority of the Ga material incorporated into the equilibrium material.

It should also be understood that after heating, the equilibrium material particles have not substantially changed in composition. Some of these equilibrium material particles have fused together and are now connected, but the composition remains substantially the same as that of the starting equilibrium material. This reduces the morphology change due to material reorganization.

### Non-liquefying, Near Equilibrium Material

Optionally, instead of using the exact equilibrium material, the material in the nucleation layer may be a material within a certain percentage away from the equilibrium material (in one or more of the material components) and is non-liquefying up to the processing temperatures used during any of the processing steps. These may be characterized as being non-liquefying, near equilibrium material.

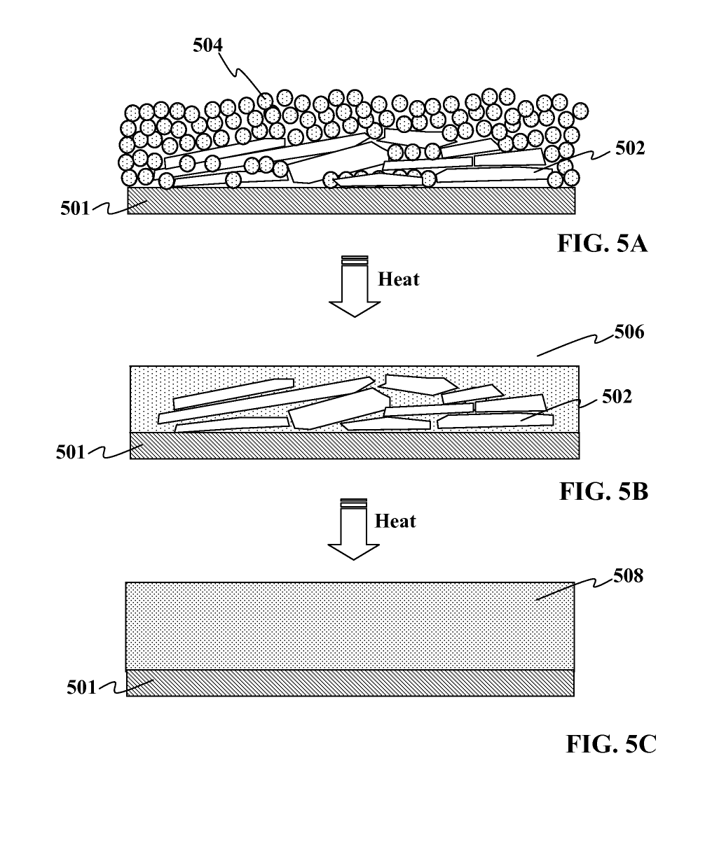

By way of nonlimiting example, FIG. 6 shows a shaded area 600 in the ternary phase diagram of Cu—In—Ga that may be a solid phase(s) through the desired range of processing temperatures.

In this manner, since the non-liquefying material is an analog of the equilibrium material, this alternative material may have many of the benefits of the equilibrium material while using a different starting composition. This non-liquefying, near equilibrium material is similar to but is not the exact equilibrium material. By way of the nonlimiting example, if the equilibrium material is a ternary material A-B-C, the analog material may be a ternary material A-B-C that is poor or rich in any one or more of these components, relative to the A-B-C equilibrium material. In one nonlimiting example, the material may be within +/−5 at % of any of the IB-IIIA-IIIA components of Cu_{2.25}In_{0.25}Ga_{0.75}. Optionally, the material may be a within +/−10 at % of any of the IB-IIIA-IIIA components of Cu_{2.25}In_{0.25}Ga_{0.75}. Optionally, the material may be a within +/−15 at % of any of the IB-IIIA-IIIA components of Cu_{2.25}In_{0.25}Ga_{0.75}. Optionally, the material may be a within +/−20 at % of any of the IB-IIIA-IIIA components of Cu_{2.25}In_{0.25}Ga_{0.75}. Optionally, the material may be a within +/−25 at % of any of the IB-IIIA-IIIA components of Cu_{2.25}In_{0.25}Ga_{0.75}. Optionally, the material may be a within +/−30 at % of any of the IB-IIIA-IIIA components of Cu_{2.25}In_{0.25}Ga_{0.75}.

Some embodiments of the nucleation material may use In+Ga higher than 42%. In some embodiments, the In+Ga between 42 and 43%. Others may optionally use In+Ga greater than 43%.

Optionally, other equilibrium materials may be in the range from Cu_{2-y}(In₁₋ₓGaₓ) to Cu_{2.25-y}(In₁₋ₓGaₓ), wherein 0.5<x<1 and −0.75≦y≦1.25. These embodiments remain copper rich and most of the changes are in the indium and/or gallium content in each material.

Optionally, the non-liquefying material may be a binary material such as but not limited to A-B, A-C, B-C, or the like that is similar to the equilibrium material but is merely missing one component of the equilibrium material.

Examples of some suitable non-liquefying solid material may be described in one embodiment as Cu_{1-x(0.38(1-y)+0.43y)}In_{0.38x(1-y)}Ga_{0.43xy}, wherein 0<x<1 and 0<y<1. Therefore, for Cu_{2.25}In_{0.25}Ga_{0.75}, x is 0.741 and y is 0.725.

In another embodiment, the composition of the material that is near equilibrium but is non-liquefying is Cu_{(1-(0.35x+0.308(1-x))y)}In_{0.14xy}Ga_{(0.308(1-x)+0.21x)y}, 0<x<1, 0.75<y<1.25.

In another embodiment, the composition of the material that is near equilibrium but is non-liquefying is Cu_{(1-0.36y)In(0.36(1-x)+0.26x)y}Ga_{0.1xy}, 0<x<1, 0.75<y<1.25.

Optionally, the way to define the relative amount of these types of alloys compared to In(O,H,X) and/or Ga(O,H,X) is to define the min and max percent group III elements in the mixture are contained in the CIG particles to meet a Cu/III mixture ratio between 1.2 and 0.5. In one embodiment, between 30% to less than 50% of the group III elements of the total mixture are found in the ternary particles. Optionally, in other embodiments, about 49% to 98% group III elements of the total mixture are found in the ternary particles.

It should also be understood that non-liquefying binary materials may also be used. Optionally, other starting materials may be binary materials in the range from Cu₅₇Ga₄₃, Cu₅₈Ga₄₂, Cu₅₉Ga₄₁, Cu₆₀Ga₄₀ Cu₆₁Ga₃₉, Cu₆₂Ga₃₈, Cu₆₃Ga₃₇, Cu₆₄Ga₃₆, Cu₆₅Ga₃₅, Cu₆₆Ga₃₄, Cu₆₇Ga₃₃, Cu₆₈Ga₃₂, Cu₆₉Ga₃ Cu₇₀Ga₃₀, Cu₇₁Ga₂₉, Cu₇₂Ga₂₈, Cu₇₃Ga₂₇, Cu₇₄Ga₂₆, Cu₇₅Ga₂₅ Cu₇₆Ga₂₄, Cu₇₇Ga₂₃, Cu₇₈Ga₂₂, Cu₇₉Ga₂₁, and/or Cu₈₀Ga₂₀. Optionally, other starting materials may be binary materials in the range from Cu₅₇Ga₄₃ to Cu₇₃Ga₂₇. Optionally, the material may be Cu₆₅Ga₃₅. Optionally, for a ternary, the material may be Cu₆₂In₁₃Ga₂₅. It should be understood that materials with higher gallium content may use Cu₅₇Ga₄₃ in combination with CuGa₂. These two materials will form the equilibrium material as these is not a single phase The common denominator is that for these embodiments, the IB-IIIA based material is non-liquefying up to a first processing temperature. Optionally, the material may exude a small amount of any one or more liquid components but some component of the original material stays solid. Optionally, at least 40% of the particle remains solid. Optionally, at least 50% of the particle remains solid. Optionally, at least 60% of the particle remains solid. Optionally, at least 70% of the particle remains solid. Optionally, at least 80% of the particle remains solid. Optionally, at least 90% of the particle remains solid. Optionally, phase change from solid to solid may occur. The exact type of materials used in the starting material may be based in part on whether the starting material is a two particle/material system, a three particle/material system, or the like.

It should be understood that the material is selected to be preferably a single phase material that is non-liquefying through the processing temperature. In one embodiment, the Cu—Ga composition Cu₇₂Ga₂₈. Optionally, the Cu—Ga composition may be Cu₈₂Ga₃₃. Optionally, the Cu—Ga composition may be Cu₅₇Ga₄₃, Cu₅₈Ga₄₂, Cu₅₉Ga₄₁, Cu₆₀Ga₄₀ Cu₆₁Ga₃₉, Cu₆₂Ga₃₈, Cu₆₃Ga₃₇, Cu₆₄Ga₃₆, Cu₆₅Ga₃₅, Cu₆₆Ga₃₄, Cu₆₇Ga₃₃, Cu₆₈Ga₃₂, Cu₆₉Ga₃₅ Cu₇₀Ga₃₀, Cu₇₁Ga₂₉, Cu₇₂Ga₂₈, Cu₇₃Ga₂₇, Cu₇₄Ga₂₆, Cu₇₅Ga₂₅ Cu₇₆Ga₂₄, Cu₇₇Ga₂₃, Cu₇₈Ga₂₂, Cu₇₉Ga₂₁, and/or Cu₈₀Ga₂₀. Optionally, the Cu—Ga composition may be Cu₆₅Ga₃₅. Optionally, a copper rich Cu—Ga composition down to Cu₅₇Ga₄₃ may be used, as shown in FIG. 6. Optionally, a copper rich Cu—In composition down to Cu₆₂In₃₈ may be used, as shown in FIG. 6. It should be understood that materials with higher gallium content may use Cu₅₇Ga₄₃ in combination with CuGa₂. Some embodiments may optionally use more than non-liquefying material. Some embodiments may use only one non-liquefying phase.

### Two Particle System Using at Least One Non-Liquefying Particle

The material composition described in the previous paragraphs relate to materials that may be used in two particle material systems, with three particle material systems, or greater numbers of particle materials. For non-particle based precursor systems, the embodiments may be described as a two material system (deposited by any known deposition system such as vacuum based deposition, electrodeposition, or the like), a three material system, or a system with four or more different materials. This section will discuss embodiments using a two material or two particle system.

### Embodiment 1

In one embodiment of the present invention, a two-particle system comprises of a precursor material using a first particle type and a second particle type. It should be understood that for non-particle based systems, the system may be described as a two material system, with the material deposited by other methods such as electrodeposition, electroplating, coevaporation, sputtering, or other techniques as known in the art. As a non-limiting example, the system may include a first particle type that is a non-liquefying ternary Cu—In—Ga particle. Although not limited to the following, the Cu—In—Ga material in this first particle may be In poor, with In about 0.25 moles or less of the IIIA material in the first particle. In this non-limiting example, the ternary particle may be Cu₂In_{0.25}Ga_{0.75}. As seen, this ternary is indium poor, relative to the amount of gallium in the ternary. In this embodiment, the In/(In+Ga) or In/III molar ratio in the particle is about 0.25. Optionally, other embodiments may use In/(In+Ga) or In/III molar ratio in the particle of 0.3 or less. Optionally, other embodiments may use In/(In+Ga) or In/III molar ratio in the particle of 0.4 or less. These increased ratios may be achieved in part by increasing In content while decreasing Ga content. These optional embodiments have increased indium concentration while still keeping the material a single phase material. A single phase is desirable in some embodiments of the present invention since the ternary material in a single phase allows the material to be size reduced and handled without substantial phase separation or loss of material from the particle. Additionally, when the second particle is an indium containing particle, too much indium in the ternary of a two particle system will create an Ga/(In+Ga) molar ratio outside our desired range in the final absorber layer.

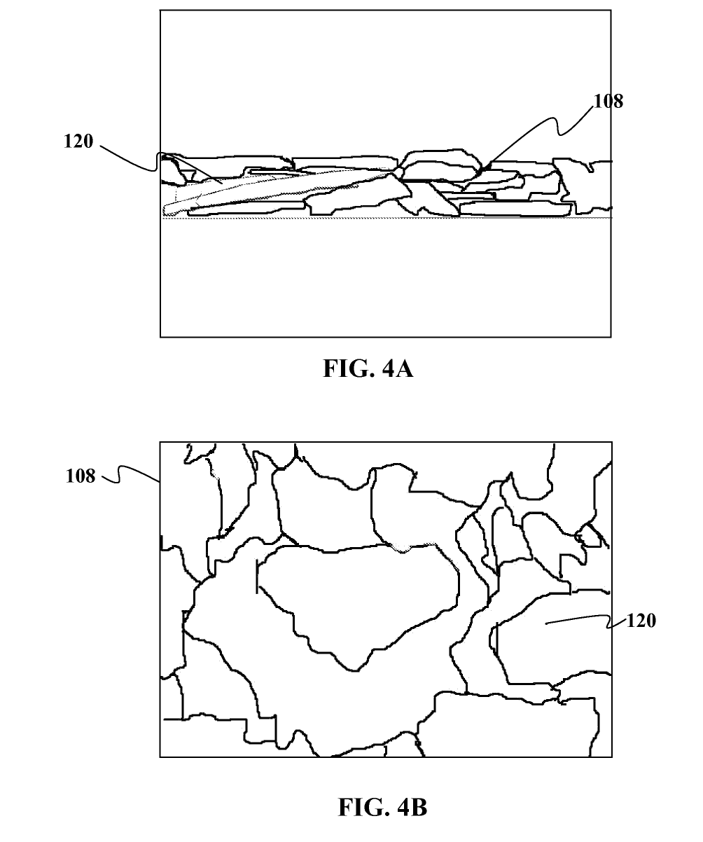

Continuing with the present embodiment, the second particle material in this example is typically an indium containing particle, wherein indium in this second particle material is less than 82%. In the present embodiment, the second particle type is InOH. The combined Cu₂In_{0.25}Ga_{0.75}+InOH material is heated in the manner similar to that shown in FIGS. 4A-4C. As seen, some particles typically are planar while others are non-planar. In this embodiment, the desired Cu/(In+Ga) molar ratio in the final absorber is in the range of about 0.6 to about 1.0. Optionally, the desired Ga/(Ga+In) molar ratio in the final absorber is in the range of about 0 to 1.0. Optionally, the desired Ga/(Ga+In) molar ratio in the final absorber is in the range of about 0.15 to 0.8. Optionally, the desired Ga/(Ga+In) molar ratio in the final absorber is in the range of about 0.2 to 0.8. Optionally, the desired Ga/(Ga+In) molar ratio in the final absorber is in the range of about 0.3 to 0.8. Optionally, the desired Ga/(Ga+In) molar ratio in the final absorber is in the range of about 0.4 to 0.8. Optionally, the desired Ga/(Ga+In) molar ratio in the final absorber is in the range of about 0.5 to 0.8. Optionally, the desired Ga/(Ga+In) molar ratio in the final absorber is in the range of about 0.6 to 0.8. Optionally, the desired Ga/(Ga+In) molar ratio in the final absorber is in the range of about 0.7 to 0.8.

Optionally, the material in the second particle may be In2O3 in combination with In or alone. This material has an In content that is less than 82%. Optionally, the material used for the second particle (or second material) has less than 70% In.

Optionally, the material in the second particle may be In—Se in combination with any of the foregoing or alone. This material has an In content that is less than 82%. Optionally, the material used for the second particle (or second material) has less than 70% In.

In one example, the indium material may be In—Ga, another Cu—In—Ga, or the like.

For the present embodiment, an approximately 0.5-2.5 micron thick layer of a precursor material containing a may be solution deposited on a substrate. The precursor material may be dispersed in a solvent such as water, alcohol or ethylene glycol with the aid of organic surfactants and/or dispersing agents described herein to form an ink. The precursor layer is annealed with a ramp-rate of 1-5 C/sec, preferably over 5° C./sec, to a temperature of about 225 to about 575° C. preferably for about 30 seconds to about 600 seconds to enhance densification and/or alloying between Cu, In, and Ga in an atmosphere containing hydrogen or nitrogen gas, where the plateau temperature not necessarily is kept constant in time. Subsequently, this annealed layer is selenized with a ramp-rate of 1-5° C./sec, preferably over 5° C./sec, to a temperature of about 225 to 600 C for a time period of about 60 seconds to about 10 minutes in Se vapor in a non-vacuum, where the plateau temperature not necessarily is kept constant in time, to form the thin-film containing one or more chalcogenide compounds containing Cu, In, Ga, and Se. Instead of this two-step approach, the layer of precursor material may be selenized without the separate annealing step in an atmosphere containing hydrogen or nitrogen gas, but may be densified and selenized in one step with a ramp-rate of 1-5 C/sec, preferably over 5 C/sec, to a temperature of 225 to 600 C for a time period of about 120 seconds to about 20 minutes in an atmosphere containing either H2Se or a mixture of H2 and Se vapor. It should be understood that other embodiments may be configured to include S vapor or H2S to create the desired CIGS or CIGSS absorber.

### Embodiment 2

In another embodiment of the present invention, yet another two-particle system will be described. The two particle system in the present embodiment comprises of a first particle type and a second particle type. As a non-limiting example, the system may include a first particle type that is a non-liquefying ternary Cu—In—Ga particle. The Cu—In—Ga material in the first particle may be In poor, with In about 0.75 moles or less of the IIIA material in the first particle. In this non-limiting example, the ternary particle may be Cu_{2.25}In_{0.25}Ga_{0.75}. As seen, this ternary is indium poor, relative to the amount of gallium in the ternary. The In/(In+Ga) molar ratio in the particle is about 0.25. Optionally, other embodiments may use In/(In+Ga) molar ratio in the particle of 0.3 or less. Optionally, other embodiments may use In/(In+Ga) molar ratio in the particle of 0.4 or less. Optionally, other embodiments may use In/(In+Ga) molar ratio in the particle of 0.5 or less. This is desirable in the present embodiment since the second particle is an indium containing particle and thus too much indium in the ternary will create an Ga/(In+Ga) molar ratio outside our desired range.

Continuing with this second embodiment, the second particle material in this example is typically an indium containing particle, wherein indium in this second particle material is less than 82%. In the present embodiment, second particle type is InOH. The combined Cu_{2.25}In_{0.25}Ga_{0.75} InOH material is heated in the manner similar to that shown in FIGS. 4A-4C. As seen, some particles typically are planar while others are non-planar. As seen, some particles typically are planar while others are non-planar. In this embodiment, the desired Cu/(In+Ga) molar ratio in the final absorber is in the range of about 0.6 to about 1.0. The desired Ga/(Ga+In) molar ratio in the final absorber is in the range of about 0.15 to 0.8. Optionally, the desired Ga/(Ga+In) molar ratio in the final absorber is in the range of about 0.2 to 0.8. Optionally, the desired Ga/(Ga+In) molar ratio in the final absorber is in the range of about 0.3 to 0.8. Optionally, the desired Ga/(Ga+In) molar ratio in the final absorber is in the range of about 0.4 to 0.8. Optionally, the desired Ga/(Ga+In) molar ratio in the final absorber is in the range of about 0.5 to 0.8. Optionally, the desired Ga/(Ga+In) molar ratio in the final absorber is in the range of about 0.6 to 0.8. Optionally, the desired Ga/(Ga+In) molar ratio in the final absorber is in the range of about 0.7 to 0.8. Simultaneously, Cu/(In+Ga) is at least 0.7. Simultaneously, IB/IIIA is at least 0.8 to 1.0. Optionally, the process results in an absorber layer with a Ga/(In+Ga) molar ratio in an uppermost region of the semiconductor film that is in the range of 0.2-0.5 and a Ga/(In+Ga) molar ratio in the entire film is in the range of 0.6-1.0.

Optionally, the material in the second particle may be In₂O₃ in combination with In or alone. This material has an In content that is less than 82%. Optionally, the material used for the second particle (or second material) has less than 70% In.

Optionally, the material in the second particle may be In—Se in combination with any of the foregoing or alone. This material has an In content that is less than 82%. Optionally, the material used for the second particle (or second material) has less than 70% In.

Other two particle systems may use binary particles instead of ternary particles. A ternary CIG may be advantageous in that one adds less InO or other In particle. This results in a shorter anneal. Both are materials analogs since they do not liquefy. CIG does provide some advantages due to it being closer to the equilibrium material.

### Embodiment 3

In another embodiment of the present invention, a two-material system comprises of a precursor material using a first material and a second material. It should be understood that for non-particle based systems, the system may be described as a two material system, with the material deposited by other methods such as electrodeposition, electroplating, coevaporation, sputtering, or other techniques as known in the art. In this manner, the layer is not actually comprised of a individual particles, but the layer is instead a uniform layer at the atomic or molecular level.

As a non-limiting example, the system may include a first material that is a non-liquefying ternary Cu—In—Ga particle. Although not limited to the following, the Cu—In—Ga material in this first material may be In poor, with In about 0.25 moles or less of the IIIA material in the first particle. In this non-limiting example, the ternary material may be Cu₂In_{0.25}Ga_{0.75}. As seen, this ternary is indium poor, relative to the amount of gallium in the ternary. In this embodiment, the In/(In+Ga) or In/III molar ratio in the material is about 0.25. Optionally, other embodiments may use In/(In+Ga) or In/III molar ratio in the material of 0.3 or less. Optionally, other embodiments may use In/(In+Ga) or In/III molar ratio in the material of 0.4 or less. These increased ratios may be achieved in part by increasing In content while decreasing Ga content. These optional embodiments have increased indium concentration while still keeping the material a single phase material. A single phase is desirable in some embodiments of the present invention since the ternary material in a single phase allows the material to be size reduced and handled without substantial phase separation or loss of material from the particle. Additionally, when the second material is an indium containing particle, too much indium in the ternary of a two particle system will create an Ga/(In+Ga) molar ratio outside our desired range in the final absorber layer. It should be understood that in some embodiments, the first material is a uniform layer while the second material is in particle form. Optionally, the first material is in particle form while the second material is a uniform layer.

Continuing with the present embodiment, the second material in this example is typically an indium containing particle, wherein indium in this second material is less than 82%. In the present embodiment, the second particle type is InOH. The combined Cu₂In_{0.25}Ga_{0.75}+InOH material is heated in the manner similar to that shown in FIGS. 4A-4C. As seen, some particles typically are planar while others are non-planar. In this embodiment, the desired Cu/(In+Ga) molar ratio in the final absorber is in the range of about 0.6 to about 1.0. Optionally, the desired Ga/(Ga+In) molar ratio in the final absorber is in the range of about 0 to 1.0. Optionally, the desired Ga/(Ga+In) molar ratio in the final absorber is in the range of about 0.15 to 0.8. Optionally, the desired Ga/(Ga+In) molar ratio in the final absorber is in the range of about 0.2 to 0.8. Optionally, the desired Ga/(Ga+In) molar ratio in the final absorber is in the range of about 0.3 to 0.8. Optionally, the desired Ga/(Ga+In) molar ratio in the final absorber is in the range of about 0.4 to 0.8. Optionally, the desired Ga/(Ga+In) molar ratio in the final absorber is in the range of about 0.5 to 0.8.

### Three Particle System

In another embodiment of the present invention, a three-particle system will be described. The three particle system typically includes a third particle that is also a group IIIA particle. It is typically not a group VIA material. However, some embodiments may include oxygen. Some embodiments may include a non-oxygen group VIA material. In one embodiment, the third particle is InOH. Optionally, the material may be Cu—In. Optionally, the material may be elemental gallium.

One such nonlimiting example would be a combination of Cu—Ga such as but not limited to Cu₈₅Ga₁₅, In(OH)₃, and elemental gallium. Yet, another example would be a combination of Cu₇₅Ga₂₅, In(OH)₃, with or without additional elemental gallium. In yet another example a combination of Cu₇₁Ga₂₉, In(OH)₃, with or without additional elemental gallium may be used. In yet another example CuGa₂ may be combined with In(OH)₃, with additional elemental copper. Optionally, Cu65Ga35, Cu11In9, and elemental gallium may be combined. Optionally, Cu52Ga48, Cu11In9, and elemental gallium may be combined. Optionally, Cu33Ga67, Cu11In9, and elemental gallium may be combined. Optionally, the Cu—Ga composition may be Cu₅₇Ga₄₃, Cu₅₈Ga₄₂, Cu₅₉Ga₄₁, Cu₆₀Ga₄₀ Cu₆₁Ga₃₉, Cu₆₂Ga₃₈, Cu₆₃Ga₃₇, Cu₆₄Ga₃₆, Cu₆₅Ga₃₅, Cu₆₆Ga₃₄, Cu₆₇Ga₃₃, Cu₆₈Ga₃₂, Cu₆₉Ga₃₅ Cu₇₀Ga₃₀, Cu₇₁Ga₂₉, Cu₇₂Ga₂₈, Cu₇₃Ga₂₇, Cu₇₄Ga₂₆, Cu₇₅Ga₂₅ Cu₇₆Ga₂₄, Cu₇₇Ga₂₃, Cu₇₈Ga₂₂, Cu₇₉Ga₂₁, and/or Cu₈₀Ga₂₀. Optionally, the Cu—Ga composition may be Cu₆₅Ga₃₅. Optionally, a copper rich Cu—Ga composition down to Cu₅₇Ga₄₃ may be used, as shown in FIG. 6. Optionally, a copper rich Cu—In composition down to Cu₆₂In₃₈ may be used, as shown in FIG. 6. It should be understood that materials with higher gallium content may use Cu₅₇Ga₄₃ in combination with CuGa₂. For any of the above embodiments, the desired Cu/(In+Ga) molar ratio in the final absorber is in the range of about 0.6 to about 1.0. The desired Ga/(Ga+In) molar ratio in the final absorber is in the range of about 0.15 to 0.8. The desired Ga/(Ga+In) molar ratio in the final absorber is in the range of about 0.3 to 0.8. Depending on the desired Ga/(Ga+In) molar ratio, the amount of Ga-source and/or In-source may be varied. Optionally, the desired Ga/(Ga+In) molar ratio in the final absorber is in the range of about 0.2 to 0.8. Optionally, the desired Ga/(Ga+In) molar ratio in the final absorber is in the range of about 0.3 to 0.8. Optionally, the desired Ga/(Ga+In) molar ratio in the final absorber is in the range of about 0.4 to 0.8. Optionally, the desired Ga/(Ga+In) molar ratio in the final absorber is in the range of about 0.5 to 0.8. Optionally, the desired Ga/(Ga+In) molar ratio in the final absorber is in the range of about 0.6 to 0.8. Optionally, the desired Ga/(Ga+In) molar ratio in the final absorber is in the range of about 0.7 to 0.8. Simultaneously, Cu/(In+Ga) is at least 0.7. Simultaneously, IB/IIIA is at least 0.8 to 1.0. Optionally, the process results in an absorber layer with a Ga/(In+Ga) molar ratio in an uppermost region of the semiconductor film that is in the range of 0.2-0.5 and a Ga/(In+Ga) molar ratio in the entire film is in the range of 0.6-1.0.

A three particle or three material (or even greater numbers of material types or particle types) may be used by one of skill in the art to adjust the values of the above ratios. In some three-particle systems, the amount of equilibrium material used in terms of total amount of group IB material in the precursor is about 10-40% by weight of the IB material in the annealed precursor layer. In one embodiment, the Ra is in the range of about 0.0744 to 0.138. In one embodiment, the Rz is in the range of about 2.2005 to 3.4006. The Ra is about 2× to 4× smoother than material that is formed without the use of equilibrium particles. The Rz is about 1.5 to 2.5 smoother. “Roughness average” or Ra is typically used since in comparing process A to process B, one is mainly interested in the “general variations in overall profile height characteristics and monitoring an established manufacturing process”. In addition, “average maximum profile” or Rz can also be used since “the presence of high peaks or deep valleys is of functional significance”.

In another example indium hydroxide may be combined with other particles of Cu—In alloy and/or elemental gallium. One such nonlimiting example would be a combination of Cu—In such as but not limited to Cu₇₀In₃₀, In(OH)₃, and elemental gallium. In yet another example In(OH)₃ would be combined with Cu—Se and Ga—Se. Yet another example would be to combine In(OH)₃ with Cu—Se and elemental gallium, or to replace the elemental gallium with a Ga—Na alloy. Yet another example would be a combination of Cu—Se, In(OH)₃, and Ga—S. Yet another example would be a combination of Cu—Se, In(OH)₃, and Ga—Se. Yet another example would be a combination of Cu—S, In(OH)₃, and Ga—Se. Yet another example would be a combination of Cu—S, In(OH)₃, and Ga—S. Yet another example would be a combination of Cu—Se, In(OH)₃, NaOH, and Ga—S. Yet another example would be a combination of copper oxide, In(OH)₃, and elemental gallium.

Optionally, salt particles and/or hydroxides particles in the ink may be used to introduce an alloy material into the final absorber layer. For example, the ink may introduce copper-indium into the absorber layer by using a precursor such as a copper-indium salt and/or a copper-indium-hydroxide. Suitable copper-indium salts include but are not limited to copper-indium salts of deprotonated organic acids, copper-indium salts of deprotonated inorganic acids, and the like. This salt and/or hydroxide may be combined with other particles wherein those other particles may be in elemental and/or alloy form. Optionally, this salt may also be combined with other salts and/or hydroxides. In this example, the solution may contain a copper-indium hydroxide combined with elemental copper and elemental gallium. Optionally, the elemental gallium may be replaced with an alloy such as Cu—Ga, In—Ga, Ga—Se or the like.

FIGS. 4A-4C shows various types of flake particles that may be used to distribute a plurality of flake particles in a substantially planar manner over the surface of the substrate.

It should be understood that although particles are shown as the physical shape of the particles, and more specifically flake particles, other non-planar shaped particles such as spherical may also be used in conjunction with or without the planar particles.

It should also be understood that other embodiments of the present invention may use deposition methods such as but not limited to electrodeposition, electroplating, electroless deposition, horizontal bath deposition of the like. In such embodiments, instead of a plurality of islands as nucleation locations, an entire layer may be used to deposit the non-liquefying precursor material. This deposition may occur in one or more steps to form a binary and/or ternary precursor material that will be processed in one or more steps into a semiconductor absorber layer. By way of nonlimiting example, the binary of group IB-IIIA non-liquefying precursor may be used and electrodeposited onto the substrate. In some embodiments, the idea is to keep the equilibrium material as close to physical shape of the deposited precursor as possible, so that the migration of materials is minimized.

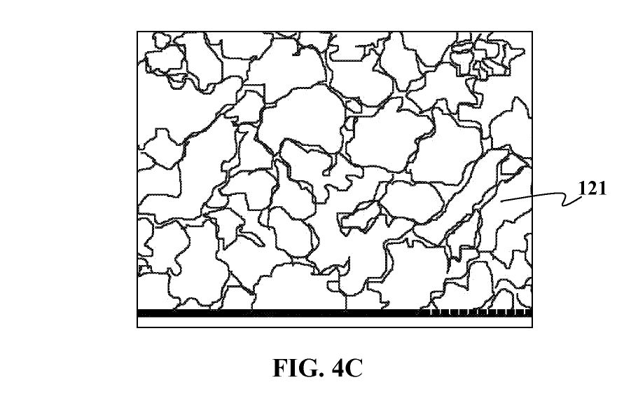

Referring now to FIG. 5A-5C, an embodiment is shown using spherical particles in conjunction with non-liquefying non-spherical particles. FIG. 5A shows how the spherical particles are positioned about and will more fully fill the cracks and crevices between the flake particles. In many of the particle based embodiments herein, the nucleation materials are flakes typically greater than 200 nm and while the other material types may be spherical such as that shown in FIG. 5A. FIG. 5B shows that heating causes the densification of the layer wherein the spherical particles liquefy to fill voids between the flake particles, thus densifying the layer. FIG. 5C shows how the densified layer in FIG. 5B is reacted to form a final semiconductor absorber layer.

As previously mentioned, FIG. 6 shows a range of ternary materials that are non-liquefying for the processing temperatures associated with one embodiment of the present invention. In one embodiment, the range includes Cu₂(InGa) to Cu₉(InGa)₄. Other embodiments include those that are non-liquefying up to 400 C. Optionally, other embodiments include those ternaries that are non-liquefying up to 410 C. Optionally, other embodiments include those ternaries that are non-liquefying up to 420 C. Optionally, other embodiments include those ternaries that are non-liquefying up to 430 C. Optionally, other embodiments include those ternaries that are non-liquefying up to 440 C. Optionally, other embodiments include those ternaries that are non-liquefying up to 450 C. Optionally, other embodiments include those ternaries that are non-liquefying up to 460 C. Optionally, other embodiments include those ternaries that are non-liquefying up to 470 C. Optionally, other embodiments include those ternaries that are non-liquefying up to 480 C. Optionally, other embodiments include those ternaries that are non-liquefying up to 490 C. Optionally, other embodiments include those ternaries that are non-liquefying up to 500 C.

In addition to being non-liquefying, it is also desirable in one embodiment of the invention that the material be a substantially planar particle and less than a certain particles size. Thus smaller flake particles enable even smaller islands, creating even more nucleation points. In one embodiment, the size of the particles in their longest dimension average about 500 nm. Optionally, the size of the particles in their longest dimension average about 500 nm or less. Optionally, the size of the particles in their longest dimension average about 600 nm or less. Optionally, the size of the particles in their longest dimension average about 700 nm or less. Optionally, the size of the particles in their longest dimension average about 800 nm or less. Optionally, the size of the particles in their longest dimension average about 900 nm or less. Optionally, the size of the particles in their longest dimension average about 1 micron or less. Optionally, the size of the particles in their longest dimension average about 1.1 micron or less. Optionally, the size of the particles in their longest dimension average about 1.2 micron or less. Optionally, the size of the particles in their longest dimension average about 1.3 micron or less. Optionally, the size of the particles in their longest dimension average about 1.4 micron or less. Optionally, the size of the particles in their longest dimension average about 1.5 micron or less.

The idea that of this embodiment of the invention is to start with a non-liquefying material composition, which if used in particle form, is of sufficiently small size to create numerous nucleation points. Without enough understanding about the desired final composition, this is, however, counter intuitive because one typically want materials to liquefy during anneal. The idea that of this embodiment of the invention is to start with same particle composition that is achieved after anneal. In non-particle based systems, such as electrodeposition, the layer will grow at the same rate (so long as the roughness is sufficiently low).

With CuGa the composition is close, but no In is present in this starting material. Non-liquefying CuGa particle is good and will not separate into liquid form in the contemplated temperature range. During processing there will be incorporation of indium into the CuGa particles. The non-liquefying particles are providing nucleation points. Evenly dispersed, they will all grow at the same time.

It should be understood that there is a balance, using current methods, of how small the particles can be. There is a balance between smaller particles and too much O₂ in the particle, which result in longer anneal time. Long anneal times may be undesirable due to material migration the longer the starting material is annealed, which may in turn create pin holes and lose Ga into the substrate.

It should be understood that in some embodiments of the present invention, it is acceptable to have some sintering of material. Sintering occurs below the liquefying point of the material but there is movement of atoms (shape change, particulate matter and get it bond to itself without liquefying).

Uniform precursors to selenization is desirable (else big islands may form and lead to degradation). Some gallium may be “kicked out” when the starting material is annealed. The plates become islands, but they still are substantially the same plate size. In one embodiment, the flakes are typically less than about 2 microns in their longest dimension when the deposited thickness about 1.5 micron thickness of the layer. Optionally, the flakes are typically less than about 1.75 microns in their longest dimension. Optionally, the flakes are typically less than about 1.5 microns in their longest dimension. Optionally, the flakes are typically less than about 1.25 microns in their longest dimension. Optionally, the flakes are typically about 1 micron or less in their longest dimension.

It should also be understood that in a particle-based system, some embodiments may have a preferential size ratio between the nucleation materials and the other materials. By way of non-limiting example, the nucleation particles are typically flake particles that are greater in size than the particles used for other materials in the precursor layer.

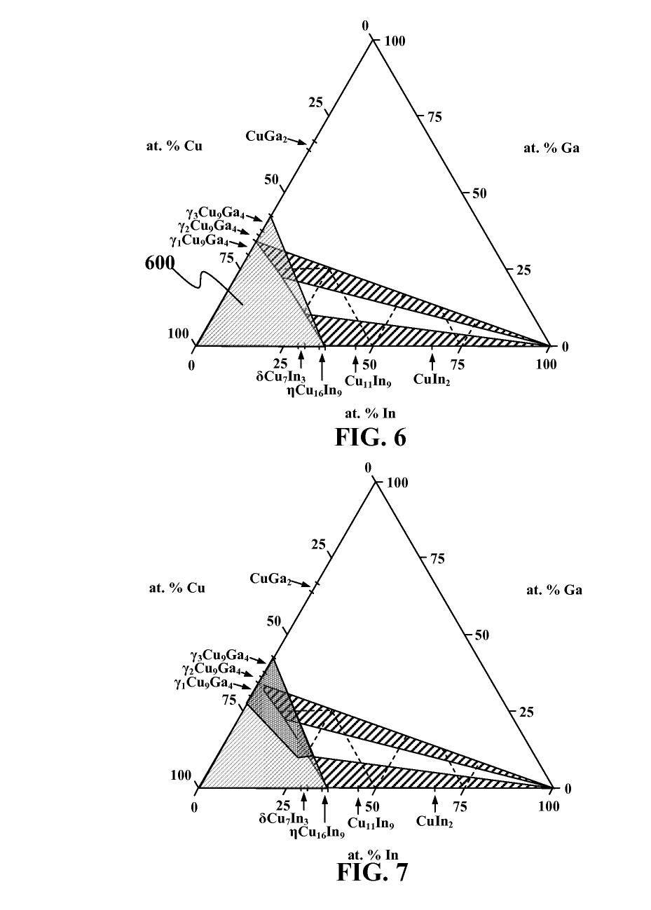

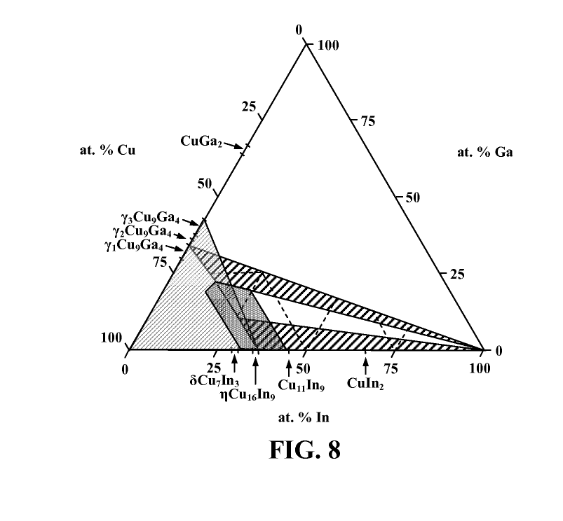

FIGS. 7 and 8 show additional possible materials that may be using singly or in combination to form the desired Cu/(In+Ga) molar ratio in the final absorber is in the range of about 0.6 to about 1.0. Optionally, the desired Ga/(Ga+In) molar ratio in the final absorber is in the range of about 0 to 1.0. Optionally, the desired Ga/(Ga+In) molar ratio in the final absorber is in the range of about 0.15 to 0.8. Optionally, the desired Ga/(Ga+In) molar ratio in the final absorber is in the range of about 0.3 to 0.8. Depending on the desired Ga/(Ga+In) molar ratio, the amount of Ga-source and/or In-source may be varied. The shaded areas show select areas within certain ranges from equilibrium material that may be used.

### Roll-to-Roll Manufacturing

A roll-to-roll manufacturing process according to the present invention will now be described. Embodiments of the invention using the solid group IIIA-based materials are well suited for use with roll-to-roll manufacturing. Specifically, in a roll-to-roll manufacturing system 400 a flexible substrate 401, e.g., aluminum foil travels from a supply roll 402 to a take-up roll 404. In between the supply and take-up rolls, the substrate 401 passes a number of applicators 406A, 406B, 406C, e.g. gravure rollers and heater units 408A, 408B, 408C. It should be understood that these heater units may be thermal heaters or be laser annealing type heaters as described herein. Each applicator deposits a different layer or sub-layer of a precursor layer, e.g., as described above. The heater units are used to anneal the different layers and/or sub-layers to form dense films. In the example depicted in FIG. 7, applicators 406A and 406B may apply different sub-layers of a precursor layer. Heater units 408A and 408B may anneal each sub-layer before the next sub-layer is deposited. Alternatively, both sub-layers may be annealed at the same time. Applicator 406C may optionally apply an extra layer of material containing chalcogen or alloy or elemental particles as described above. Heater unit 408C heats the optional layer and precursor layer as described above. Note that it is also possible to deposit the precursor layer (or sub-layers) then deposit any additional layer and then heat all three layers together to form the IB-IIIA-chalcogenide compound film used for the photovoltaic absorber layer. The roll-to-roll system may be a continuous roll-to-roll and/or segmented roll-to-roll, and/or batch mode processing.

### Photovoltaic Device

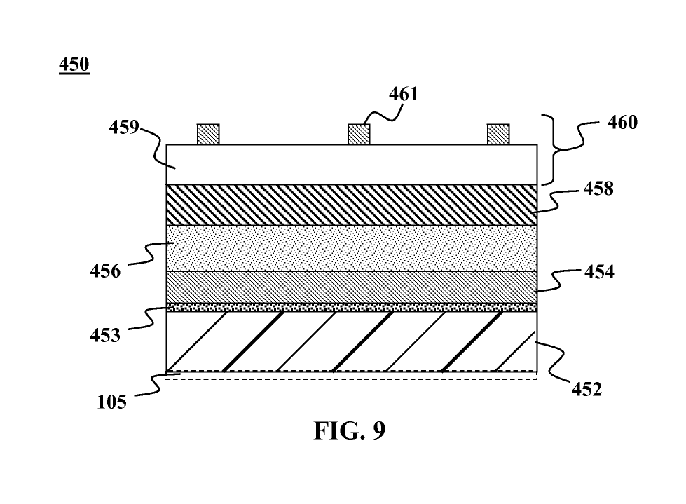

Referring now to FIG. 9, the films fabricated as described above using solid group IIIA-based materials may serve as an absorber layer in a photovoltaic device, module, or solar panel. An example of such a photovoltaic device 450 is shown in FIG. 9. The device 450 includes a base substrate 452, an optional adhesion layer 453, a base or back electrode 454, a p-type absorber layer 456 incorporating a film of the type described above, an n-type semiconductor thin film 458 and a transparent electrode 460. By way of example, the base substrate 452 may be made of a metal foil, a polymer such as polyimides (PI), polyamides, polyetheretherketone (PEEK), Polyethersulfone (PES), polyetherimide (PEI), polyethylene naphtalate (PEN), Polyester (PET), related polymers, a metallized plastic, and/or combination of the above and/or similar materials. By way of nonlimiting example, related polymers include those with similar structural and/or functional properties and/or material attributes. The base electrode 454 is made of an electrically conductive material. By way of example, the base electrode 454 may be of a metal layer whose thickness may be selected from the range of about 0.1 micron to about 25 microns. An optional intermediate layer 453 may be incorporated between the electrode 454 and the substrate 452. The transparent electrode 460 may include a transparent conductive layer 459 and a layer of metal (e.g., Al, Ag, Cu, or Ni) fingers 461 to reduce sheet resistance. Optionally, the layer 453 may be a diffusion barrier layer to prevent diffusion of material between the substrate 452 and the electrode 454. The diffusion barrier layer 453 may be a conductive layer or it may be an electrically nonconductive layer. As nonlimiting examples, the layer 453 may be composed of any of a variety of materials, including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. Although not limited to the following, the thickness of this layer can range from 10 nm to 50 nm. In some embodiments, the layer may be from 10 nm to 30 nm. Optionally, an interfacial layer may be located above the electrode 454 and be comprised of a material such as including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing.

The n-type semiconductor thin film 458 serves as a junction partner between the compound film and the transparent conducting layer 459. By way of example, the n-type semiconductor thin film 458 (sometimes referred to as a junction partner layer) may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also be configured for use in a continuous roll-to-roll and/or segmented roll-to-roll and/or a batch mode system.

The transparent conductive layer 459 may be inorganic, e.g., a transparent conductive oxide (TCO) such as but not limited to indium tin oxide (ITO), fluorinated indium tin oxide, zinc oxide (ZnO) or aluminum doped zinc oxide, or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive layer may include a transparent conductive polymeric layer, e.g. a transparent layer of doped PEDOT (Poly-3,4-Ethylenedioxythiophene), carbon nanotubes or related structures, or other transparent organic materials, either singly or in combination, which can be deposited using spin, dip, or spray coating, and the like or using any of various vapor deposition techniques. Optionally, it should be understood that intrinsic (non-conductive) i-ZnO may be used between CdS and Al-doped ZnO. Combinations of inorganic and organic materials can also be used to form a hybrid transparent conductive layer. Thus, the layer 459 may optionally be an organic (polymeric or a mixed polymeric-molecular) or a hybrid (organic-inorganic) material. Examples of such a transparent conductive layer are described e.g., in commonly-assigned US Patent Application Publication Number 20040187317, which is incorporated herein by reference.

Those of skill in the art will be able to devise variations on the above embodiments that are within the scope of these teachings. For example, it is noted that in embodiments of the present invention, portions of the IB-IIIA precursor layers (or certain sub-layers of the precursor layers or other layers in the stack) may be deposited using techniques other than particle-based inks. For example precursor layers or constituent sub-layers may be deposited using any of a variety of alternative deposition techniques including but not limited to solution-deposition of spherical nanopowder-based inks, vapor deposition techniques such as ALD, evaporation, sputtering, CVD, PVD, electroplating and the like.

Referring now to FIG. 5A, it should also be understood that the embodiments of the present invention may also be used on a rigid substrate 600. By way of nonlimiting example, the rigid substrate 600 may be glass, soda-lime glass, steel, stainless steel, aluminum, polymer, ceramic, coated polymer, or other rigid material suitable for use as a solar cell or solar module substrate. A high speed pick-and-place robot 602 may be used to move rigid substrates 600 onto a processing area from a stack or other storage area. In FIG. 5A, the substrates 600 are placed on a conveyor belt which then moves them through the various processing chambers. Optionally, the substrates 600 may have already undergone some processing by the time and may already include a precursor layer on the substrate 600. Other embodiments of the invention may form the precursor layer as the substrate 600 passes through the chamber 606. Any of the foregoing may be adapted for use with a laser annealing system that selectively processes target layers over substrates. This may occur in one or more of the chambers through which the substrate 600 passes.

FIG. 5B shows another embodiment of the present system where a pick-and-place robot 610 is used to position a plurality of rigid substrates on a carrier device 612 which may then be moved to a processing area as indicated by arrow 614. This allows for multiple substrates 600 to be loaded before they are all moved together to undergo processing. Source 662 may provide a source of processing gas to provide a suitable atmosphere to create the desired semiconductor film. In one embodiment, chalcogen vapor may be provided by using a partially or fully enclosed chamber with a chalcogen source 662 therein or coupled to the chamber. Any of the foregoing may be adapted for use with a laser annealing system that selectively processes target layers over substrates.

### Chalcogen Vapor Environment

Yet another embodiment of the present invention will now be described. In this embodiment for use with a metal-ion based precursor material, it should be understood that a chalcogen vapor may be used to provide a chalcogen atmosphere to process a film into the desired absorber layer. Optionally, in one embodiment, an overpressure from chalcogen vapor is used to provide a chalcogen atmosphere. FIG. 6A shows a chamber 1050 with a substrate 1052 having a layer 1054 and a precursor layer 1056. Extra sources 1058 of chalcogen may be included in the chamber and are brought to a temperature to generate chalcogen vapor as indicated by lines 1060. In one embodiment of the present invention, the chalcogen vapor is provided to have a partial pressure of the chalcogen present in the atmosphere greater than or equal to the vapor pressure of chalcogen that would be required to maintain a partial chalcogen pressure at the processing temperature and processing pressure to minimize loss of chalcogen from the precursor layer, and if desired, provide the precursor layer with additional chalcogen. The partial pressure is determined in part on the temperature that the chamber 1050 or the precursor layer 1056 is at. It should also be understood that the chalcogen vapor is used in the chamber 1050 at a non-vacuum pressure. In one embodiment, the pressure in the chamber is at about atmospheric pressure. Per the ideal gas law PV=nRT, it should be understood that the temperature influences the vapor pressure. In one embodiment, this chalcogen vapor may be provided by using a partially or fully enclosed chamber with a chalcogen source 1062 therein or coupled to the chamber. In another embodiment using a more open chamber, the chalcogen overpressure may be provided by supplying a source producing a chalcogen vapor. The chalcogen vapor may serve to help keep the chalcogen in the film. Thus, the chalcogen vapor may or may not be used to provide excess chalcogen. It may serve more to keep the chalcogen present in the film than to provide more chalcogen into the film.

In yet another embodiment, it is shown that the present invention may be adopted for use with a roll-to-roll system where the substrate 1070 carrying the precursor layer may be flexible and configured as rolls 1072 and 1074. The chamber 1076 may be at vacuum or non-vacuum pressures. The chamber 1076 may be designed to incorporate a differential valve design to minimize the loss of chalcogen vapor at the chamber entry and chamber exit points of the roll-to-roll substrate 1070.

In a still further embodiment of the present invention, the system uses a chamber 1090 of sufficient size to hold the entire substrate, including any rolls 1072 or 1074 associated with using a roll-to-roll configuration.

### Extra Source of Chalcogen

It should be understood that the present invention using metal ion precursors or hydroxides may also use an extra chalcogen source in a manner similar to that described in copending, U.S. patent application Ser. No. 11/290,633 (Attorney Docket No. NSL-045), wherein the precursor material contains the previous materials and 1) chalcogenides such as, but not limited to, copper selenide, and/or indium selenide and/or gallium selenide and/or 2) a source of extra chalcogen such as, but not limited to, Se or S nanoparticles less than about 200 nanometers in size. In one nonlimiting example, the chalcogenide and/or the extra chalcogen may be in the form of microflakes and/or nanoflakes while the extra source of chalcogen may be flakes and/or non-flakes. The chalcogenide microflakes may be one or more binary alloy chalcogenides such as, but not limited to, group IB-binary chalcogenide nanoparticles (e.g. group IB non-oxide chalcogenides, such as Cu—Se, Cu—S or Cu—Te) and/or group IIIA-chalcogenide nanoparticles (e.g., group IIIA non-oxide chalcogenides, such as Ga(Se, S, Te), In(Se, S, Te) and Al(Se, S, Te). In other embodiments, the microflakes may be non-chalcogenides such as but not limited to group IB and/or IIIA materials like Cu—In, Cu—Ga, and/or In—Ga. If the chalcogen liquefys at a relatively low temperature (e.g., 220° C. for Se, 120° C. for S) the chalcogen is already in a liquid state and makes good contact with the microflakes. If the microflakes and chalcogen are then heated sufficiently (e.g., at about 375° C.), the chalcogen reacts with the chalcogenides to form the desired IB-IIIA-chalcogenide material.

Although not limited to the following, the chalcogenide particles may be obtained starting from a binary chalcogenide feedstock material, e.g., micron size particles or larger. Examples of chalcogenide materials available commercially are listed below in Table I.

TABLE I

| Chemical | Formula | Typical % Purity |
|---|---|---|
| Aluminum selenide | Al2Se3 | 99.5 |
| Aluminum sulfide | Al2S3 | 98 |
| Aluminum sulfide | Al2S3 | 99.9 |
| Aluminum telluride | Al2Te3 | 99.5 |
| Copper selenide | Cu—Se | 99.5 |
| Copper selenide | Cu2Se | 99.5 |
| Gallium selenide | Ga2Se3 | 99.999 |
| Copper sulfide | Cu2S(may be Cu1.8-2S) | 99.5 |
| Copper sulfide | CuS | 99.5 |
| Copper sulfide | CuS | 99.99 |
| Copper telluride | CuTe(generally Cu1.4Te) | 99.5 |
| Copper telluride | Cu2Te | 99.5 |
| Gallium sulfide | Ga2S3 | 99.95 |
| Gallium sulfide | GaS | 99.95 |
| Gallium telluride | GaTe | 99.999 |
| Gallium telluride | Ga2Te3 | 99.999 |
| Indium selenide | In2Se3 | 99.999 |
| Indium selenide | In2Se3 | 99.99% |
| Indium selenide | In2Se3 | 99.9 |
| Indium selenide | In2Se3 | 99.9 |
| Indium sulfide | InS | 99.999 |
| Indium sulfide | In2S3 | 99.99 |
| Indium telluride | In2Te3 | 99.999 |
| Indium telluride | In2Te3 | 99.999 |

Examples of chalcogen powders and other feedstocks commercially available are listed in Table II below.

TABLE II

| Chemical | Formula | Typical % Purity |
|---|---|---|
| Selenium metal | Se | 99.99 |
| Selenium metal | Se | 99.6 |
| Selenium metal | Se | 99.6 |
| Selenium metal | Se | 99.999 |
| Selenium metal | Se | 99.999 |
| Sulfur | S | 99.999 |
| Tellurium metal | Te | 99.95 |
| Tellurium metal | Te | 99.5 |
| Tellurium metal | Te | 99.5 |
| Tellurium metal | Te | 99.9999 |
| Tellurium metal | Te | 99.99 |
| Tellurium metal | Te | 99.999 |
| Tellurium metal | Te | 99.999 |
| Tellurium metal | Te | 99.95 |
| Tellurium metal | Te | 99.5 |

### Printing a Layer of the Extra Source of Chalcogen

Referring now to FIG. 1C, another embodiment of the present invention will now be described. An extra source of chalcogen may be provided as a discrete layer 107 containing an extra source of chalcogen such as, but not limited to, elemental chalcogen particles over a microflake or non-flake precursor layer. By way of example, and without loss of generality, the chalcogen particles may be particles of selenium, sulfur or tellurium. Heat is applied to the precursor layer and the layer 107 containing the chalcogen particles to heat them to a temperature sufficient to liquefy the chalcogen particles and to react the chalcogen particles with the elements in the precursor layer 106. It should be understood that the microflakes may be made of a variety of materials include but not limited to group IB elements, group IIIA elements, and/or group VIA elements. The reaction of the chalcogen particles 107 with the elements of the precursor layer 106 forms a compound film 110 of a group IB-IIIA-chalcogenide compound. Preferably, the group IB-IIIA-chalcogenide compound is of the form CuIn₁₋ₓ₋GaₓSe_{2(1-y)}S_{2y}, where 0≦x≦1 and 0≦y≦1. It should be understood that in some embodiments, the precursor layer 106 may be densified prior to application of the layer 107 with the extra source of chalcogen. In other embodiments, the precursor layer 106 is not pre-heated and the layers 106 and 107 are heated together.

In one embodiment of the present invention, the precursor layer 106 may be between about 4.0 to about 0.5 microns thick. The layer 107 containing chalcogen particles may have a thickness in the range of about 4.0 microns to about 0.5 microns. The chalcogen particles in the layer 107 may be between about 1 nanometer and about 25 microns in size, preferably between about 25 nanometers and about 300 nanometers in size. It is noted that the chalcogen particles may be initially larger than the final thickness of the IB-IIIA-VIA compound film 110. The chalcogen particles 108 may be mixed with solvents, carriers, dispersants etc. to prepare an ink or a paste that is suitable for wet deposition over the precursor layer 106 to form the layer. Alternatively, the chalcogen particles may be prepared for deposition on a substrate through dry processes to form the layer 107. It is also noted that the heating of the layer 107 containing chalcogen particles may be carried out by an RTA process, e.g., as described above.

The chalcogen particles (e.g., Se or S) may be formed in several different ways. For example, Se or S particles may be formed starting with a commercially available fine mesh powder (e.g., 200 mesh/75 micron) and ball milling the powder to a desirable size. A typical ball milling procedure may use a ceramic milling jar filled with grinding ceramic balls and a feedstock material, which may be in the form of a powder, in a liquid medium. When the jar is rotated or shaken, the balls shake and grind the powder in the liquid medium to reduce the size of the particles of the feedstock material. Optionally, the process may include dry (pre-) grinding of bigger pieces of material such as but not limited to Se. The dry-grinding may use pieces 2-6 mm and smaller, but it would be able to handle bigger pieces as well. Note that this is true for all size reductions where the process may start with bigger feedstock materials, dry grinding, and subsequently starting wet grinding (such as but not limited to ball milling). The mill itself may range from a small media mill to a horizontal rotating ceramic jar.

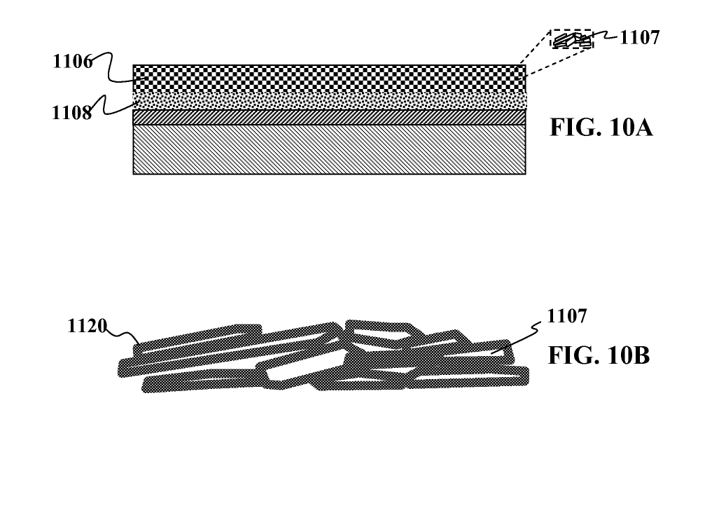

As seen in FIG. 10A, it should also be understood that in some embodiments, the layer 1108 of chalcogen particles may be formed below the precursor layer 1106. This position of the layer 1108 still allows the chalcogen particles to provide a sufficient surplus of chalcogen to the precursor layer 1106 to fully react with the group IB and group IIIA elements in layer 1106. Additionally, since the chalcogen released from the layer 1108 may be rising through the layer 1106, this position of the layer 1108 below layer 1106 may be beneficial to generate greater intermixing between elements. The thickness of the layer 1108 may be in the range of about 4.0 microns to about 0.5 microns. In still other embodiments, the thickness of layer 1108 may be in the range of about 500 nm to about 50 nm. In one nonlimiting example, a separate Se layer of about 100 nm or more might be sufficient. The coating of chalcogen may incorporate coating with powder, Se evaporation, or other Se deposition method such as but not limited to chemical vapor deposition (CVD), physical vapor deposition (PVD), atomic layer deposition (ALD), electroplating, and/or similar or related methods using singly or in combination. Other types of material deposition technology may be used to get Se layers thinner than 0.5 microns or thinner than 1.0 micron. It should also be understood that in some embodiments, the extra source of chalcogen is not limited to only elemental chalcogen, but in some embodiments, may be an alloy and/or solution of one or more chalcogens.

Optionally, it should be understood that the extra source of chalcogen may be mixed with and/or deposited within the precursor layer, instead of as a discrete layer. In one embodiment of the present invention, oxygen-free particles or substantially oxygen-free particles of chalcogen could be used. If the chalcogen is used with microflakes and/or plate shaped precursor materials, densification might not end up an issue due to the higher density achieved by using planar particles, so there is no reason to exclude printing Se and/or other source of chalcogen within the precursor layer as opposed to a discrete layer. This may involve not having to heat the precursor layer to the previous processing temperatures. In some embodiments, this may involve forming the film without heating above 400° C. In some embodiments, this may involve not having to heat above about 300° C.

In still other embodiments of the present invention, multiple layers of material may be printed and reacted with chalcogen before deposition of the next layer. One nonlimiting example would be to deposit a Cu—In—Ga layer, anneal it, then deposit an Se layer then treat that with RTA, follow that up by depositing another precursor layer rich in Ga, followed by another deposition of Se, and finished by a second RTA treatment. More generically, this may include forming a precursor layer (either heat or not) then coating a layer of the extra source of chalcogen (then heat or not) then form another layer of more precursor (heat or not) and then for another layer of the extra source of chalcogen (then heat or not) and repeat as many times as desired to grade the composition or nucleating desired crystal sizes. In one nonlimiting example, this may be used to grade the gallium concentration. In another embodiment, this may be used to grade the copper concentration. In yet another embodiment, this may be used to grade the indium concentration. In a still further embodiment, this may be used to grade the selenium concentration. In yet another embodiment this may be used to grade the selenium concentration. Another reason would be to first grow copper rich films to get big crystals and then to start adding copper-poor layers to get the stoichiometry back. Of course this embodiment can combined to allow the chalcogen to be deposited in the precursor layer for any of the steps involved.

FIG. 10B shows core-shell microflakes in which the core is a microflake 1107 and the shell 1120 is a chalcogen and/or chalcogenide coating. Up to 10% to 8% by weight of the particle may be oxygen. Up to 8% to 6% by weight of the particle may be oxygen. In some embodiments, the shell is an oxide shell that is the same or different from the material in the core. This oxygen may be concentrated in the shell. Optionally, it may be dispersed through the particle. Optionally, it may be in both the shell and through out the particle. As a nonlimiting example, the core may be a mix of elemental particles of groups IB (e.g., Cu) and/or IIIA (e.g., Ga and In), which may be obtained by size reducing of feedstock to a desired size. Examples of elemental feedstock materials available are listed in Table III below. The core may also be a chalcogenide core or other material as described herein.

TABLE III

| Chemical | Formula | Typical % Purity |
|---|---|---|
| Copper metal | Cu | 99.99 |
| Copper metal | Cu | 99 |
| Copper metal | Cu | 99.5 |
| Copper metal | Cu | 99.5 |
| Copper metal | Cu | 99 |
| Copper metal | Cu | 99.999 |
| Copper metal | Cu | 99.999 |
| Copper metal | Cu | 99.9 |
| Copper metal | Cu | 99.5 |
| Copper metal | Cu | 99.9 (O₂ typ. 2-10%) |
| Copper metal | Cu | 99.99 |
| Copper metal | Cu | 99.997 |
| Copper metal | Cu | 99.99 |
| Gallium metal | Ga | 99.999999 |
| Gallium metal | Ga | 99.99999 |
| Gallium metal | Ga | 99.99 |
| Gallium metal | Ga | 99.9999 |
| Gallium metal | Ga | 99.999 |
| Indium metal | In | 99.9999 |
| Indium metal | In | 99.999 |
| Indium metal | In | 99.999 |
| Indium metal | In | 99.99 |
| Indium metal | In | 99.999 |
| Indium metal | In | 99.99 |
| Indium metal | In | 99.99 |

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, traditional thermal annealing may also be used in conjunction with laser annealing. For example, with any of the above embodiments, microflakes may be replaced by and/or mixed with nanoflakes wherein the lengths of the planar nanoflakes are about 500 nm to about 1 nm. As a nonlimiting example, the nanoflakes may have lengths and/or largest lateral dimension of about 300 nm to about 10 nm. In other embodiments, the nanoflakes may be of thickness in the range of about 200 nm to about 20 nm. In another embodiment, these nanoflakes may be of thickness in the range of about 100 nm to about 10 nm. In one embodiment, these nanoflakes may be of thickness in the range of about 200 nm to about 20 nm. As mentioned, some embodiments of the invention may include both microflakes and nanoflakes. Other may include flakes that are exclusively in the size range of microflakes or the size range of nanoflakes. With any of the above embodiments, the microflakes may be replaced and/or combined with microrods which are substantially linear, elongate members. Still further embodiments may combine nanorods with microflakes in the precursor layer. The microrods may have lengths between about 500 nm to about 1 nm. In another embodiment, the nanorods may have lengths between about 500 nm and 20 nm. In yet another embodiment, the nanorods may have lengths between about 300 nm and 30 nm. Any of the above embodiments may be used on rigid substrate, flexible substrate, or a combinations of the two such as but not limited to a flexible substrate that become rigid during processing due to its material properties. In one embodiment of the present invention, the particles may be plates and/or discs and/or flakes and/or wires and/or rods of micro-sized proportions. In another embodiment of the present invention, the particles may be nanoplates and/or nanodiscs and/or nanoflakes and/or nanowires and/or nanorods of nano-sized proportions. Again, any of the foregoing may also be combined with spherical particles in a suspension. Some embodiments may have all spherical particles, all non-spherical particles, and/or mixtures of particles of various shapes. It should be understood that the solid group IIIA-based particles may be used in single or multiple combination with particles of other shapes and/or composition. This may include shapes such as but not limited to spherical, planar, flake, other non-spherical, and/or single or multiple combinations of the foregoing. As for materials, this may include alloys, elementals, chalcogenides, inter-metallics, solid-solutions and/or single or multiple combinations of the foregoing in any shape or form. Use of solid particles with dispersions and/or emulsions of the foregoing is also envisioned. The solid solutions are described in pending U.S. patent application Ser. No. 10/474,259 and published as US20040219730, fully incorporated herein by reference for all purposes. The following applications are also fully incorporated herein by reference: 11/395,438, 11/395,668, and 11/395,426 both filed Mar. 30, 2006. Any of the embodiments described in those applications may be adapted for use with the particles described herein.

For any of the above embodiments, it should be understood that in addition to the aforementioned, the temperature used during annealing may also vary over different time periods of precursor layer processing. As a nonlimiting example, the heating may occur at a first temperature over an initial processing time period and proceed to other temperatures for subsequent time periods of the processing. Optionally, the method may include intentionally creating one or more temperature dips so that, as a nonlimiting example, the method comprises heating, cooling, heating, and subsequent cooling. Some embodiments may use a two-step absorber growth (non-reactive anneal for densification followed by reactive anneal) without cool-down and ramp-up between densification and selenization/sulfurization. Various heating methods, including not heating the substrate, but only the precursor layer (laser) may be used. Others heating techniques may use muffle heating, convection heating, IR-heating. Some embodiments may use the same or different techniques for heating the top surface and bottom surface of the substrate. Basically, all heating mechanisms, being conduction, convection, and radiation may be used. All temperature gradients within the web (across the thickness), being uniformly heated from bottom to top, and/or heating with a huge temperature gradient from bottom (low T) to top (high T), e.g. with a laser, and covering all web transport mechanisms through the furnace (including but not limited to being free-span through the module, dragging over a dense or partially open surface, or relying on a belt), orientation of the furnace, horizontally, vertically, or anything in between.

For any of the above embodiments, it is also possible to have two or more elements of IB elements in the chalcogenide particle and/or the resulting film. Although the description herein uses an ink, it should be understood that in some embodiments, the ink may have the consistency of a paste or slurry. It should be understood that the deposition methods for use with depositing precursor material(s) may include one or more of the following: solution-deposition of particulates, like coating, printing, and spraying, sol-gel, electro(less) deposition (HBP, CBD, e-Dep), precipitations, (chemical) vapor deposition, sputtering, evaporation, ion plating, extrusion, cladding, thermal spray, where several of these methods can be plasma-enhanced) and precursor/film-conversion methods, where the latter can be either chemically, physically, and/or mechanically, and covers both partial and complete changes of the precursor/film and/or surface only.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

For example, still other embodiments of the present invention may use a Cu—In precursor material wherein Cu—In contributes less than about 50 percent of both Cu and In found in the precursor material. The remaining amount is incorporated by elemental form or by non IB-IIIA alloys. Thus, a Cu₁₁In₉ may be used with elemental Cu, In, and Ga to form a resulting film. In another embodiment, instead of elemental Cu, In, and Ga, other materials such as Cu—Se, In—Se, and/or Ga—Se may be substituted as source of the group IB or IIIA material. Optionally, in another embodiment, the IB source may be any particle that contains Cu without being alloyed with In and Ga (Cu, Cu—Se). The IIIA source may be any particle that contains In without Cu (In—Se, In—Ga—Se) or any particle that contains Ga without Cu (Ga, Ga—Se, or In—Ga—Se). Other embodiments may have these combinations of the IB material in a nitride or oxide form. Still other embodiments may have these combinations of the IIIA material in a nitride or oxide form. The present invention may use any combination of elements and/or selenides (binary, ternary, or multinary) may be used. Optionally, some other embodiments may use oxides such as In₂O₃ to add the desired amounts of materials. It should be understood for any of the above embodiments that more than one solid solution may be used, multi-phasic alloys, and/or more general alloys may also be used. For any of the above embodiments, the annealing process may also involve exposure of the compound film to a gas such as H₂, CO, N₂, Ar, H₂Se, Se vapor, S vapor, or other group VIA containing vapor. There may be a two stage process where there is an initial anneal in a non group-VIA based atmosphere and then a second or more heating in group VIA-based atmosphere. There may be a two stage process where there is an initial anneal in a non group-VIA based atmosphere and then a second heating in a non-group VIA based atmosphere, wherein VIA material is placed directly on the stack for the second heating and additional is the VIA-containing vapor is not used. Alternatively, some may use a one stage process to create a final film, or a multi-stage process where each heating step use a different atmosphere.

It should also be understood that several intermediate solid solutions may also be suitable for use according to the present invention. As nonlimiting examples, a composition in the δ phase for Cu—In (about 42.52 to about 44.3 wt % In) and/or a composition between the δ phase for Cu—In and Cu₁₆In₉ may be suitable inter-metallic materials for use with the present invention to form a group IB-IIIA-VIA compound. It should be understood that these inter-metallic materials may be mixed with elemental or other materials such as Cu—Se, In—Se, and/or Ga—Se to provide sources of the group IB or IIIA material to reach the desired stoichiometric ratios in the final compound. Other nonlimiting examples of inter-metallic material include compositions of Cu—Ga containing the following phases: γ₁ (about 31.8 to about 39.8 wt % Ga), γ₂ (about 36.0 to about 39.9 wt % Ga), γ₃ (about 39.7 to about −44.9 wt % Ga), the phase between γ₂ and γ₃, the phase between the terminal solid solution and γ₁, and θ (about 66.7 to about 68.7 wt % Ga). For Cu—Ga, a suitable composition is also found in the range in between the terminal solid-solution of and the intermediate solid-solution next to it. Advantageously, some of these inter-metallic materials may be multi-phasic which are more likely to lead to brittle materials that can be mechanically milled. Phase diagrams for the following materials may be found in ASM Handbook, Volume 3 Alloy Phase Diagrams (1992) by ASM International and fully incorporated herein by reference for all purposes. Some specific examples (fully incorporated herein by reference) may be found on pages 2-168, 2-170, 2-176, 2-178, 2-208, 2-214, 2-257, and/or 2-259. It should also be understood that a particle may have portions that are of a solid alloy and portions that are phase separated into individual elements or other alloys that are liquid.

It should be understood that any of the embodiments herein may be adapted for use in a one step process, or a two step process, or a multi-step process for forming a photovoltaic absorber layer. One step processes do not require a second follow-up process to convert the film into an absorber layer. A two step process typically creates a film that uses a second process to convert the film into an absorber layer. Additionally, some embodiments may have anywhere from about 0 to about 5 wt % oxygen in the shell.

It should be understood that the particles as described herein may be used with solids, solid solutions, intermetallics, nanoglobules, emulsions, nanoglobule, emulsion, or other types of particles. It should also be understood that prior to deposition of any material on the substrate, the metal foil may undergo conditioning (cleaning, smoothening, and possible surface treatment for subsequent steps), such as but not limited to corona cleaning, wet chemical cleaning, plasma cleaning, ultrasmooth re-rolling, electro-polishing, and/or CMP slurry polishing.

Furthermore, those of skill in the art will recognize that any of the embodiments of the present invention can be applied to almost any type of solar cell material and/or architecture. For example, the absorber layer in the solar cell may be an absorber layer comprised of copper-indium-gallium-selenium (for CIGS solar cells), CdSe, CdTe, Cu(In,Ga)(S,Se)₂, Cu(In,Ga,Al)(S,Se,Te)₂, (Cu,Au,Ag)(In,Ga,Al)(S,Se,Te)₂, Cu—In, In—Ga, Cu—Ga, Cu—In—Ga, Cu—In—Ga—S, Cu—In—Ga—Se, other absorber materials, II-VI materials, IB-VI materials, CuZnTe, CuTe, ZnTe, IB-IIB-IVA-VIA absorbers, or other alloys, and/or combinations of the above, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, US 20040219730 and US 2005/0183767, US 2007-0163643, US 2007-0163642, US 2007-0163644, and US 2007-0163641 are fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A method comprising:
providing an ink that contains at least one type of particles where these particles in volume largely consist of the majority (by volume) high-liquefying phase in the single-phase or multi-phase film obtained after heat treatment;
processing the precursor layer in one or more steps to form a photovoltaic absorber layer.

2. The method of claim 1 wherein a second type of particle having less than 82% In is used in the ink.

3. The method of claim 1 wherein InOH3 is used in the ink.

4. The method of claim 1 further comprising dispersant removal techniques after the ink is deposited on a substrate.

5. The method of claim 1 wherein Cu—In—Ga contain an oxygen content between about 6 to 8 wt %.

6. The method of claim 1 wherein processing comprises reacting in a single step process.

7. The method of claim 1 wherein processing comprises reacting in a multi-step process.

8. The method of claim 1 wherein processing comprises reacting in a bilayer process.

9. The method of claim 1 wherein processing comprises reacting in a trilayer process.

10. The method of claim 1 further comprising depositing a group VIA on top of as-coated precursor.

11. The method of claim 1 further comprising depositing a group VIA on top of as-annealed precursor.

12. The method of claim 1 wherein the precursor layer comprises of Cu—Ga, indium hydroxide, and elemental gallium.

13. The method of claim 1 wherein the precursor layer comprises of Cu₈₅Ga₁₅, In(OH)₃, and elemental gallium.

14. The method of claim 1 wherein the precursor layer further comprises of copper nanoparticles and indium-gallium hydroxide.

15. The method of claim 1 wherein the precursor layer further comprises copper-gallium and indium hydroxide without separate elemental gallium.

16. The method of claim 1 wherein processing comprises annealing with a ramp-rate of 1-5 C/sec, preferably over 5 C/sec, to a temperature of about 225 to 550° C.

17. The method of claim 1 wherein processing comprises annealing with a ramp-rate of 1-5 C/sec, preferably over 5 C/sec, to a temperature of about 225 to 550° C. preferably for about 30 seconds to about 600 seconds to enhance conversion of indium hydroxide, densification and/or alloying between Cu, In, and Ga in an atmosphere containing hydrogen gas, where the plateau temperature not necessarily is kept constant in time.

18. The method of claim 1 wherein processing further comprise selenizing this annealed layer with a ramp-rate of over 5 C/sec, to a temperature of about 225 to 575 C for a time period of about 60 seconds to about 10 minutes in Se vapor in a non-vacuum atmosphere, where the plateau temperature not necessarily is kept constant in time, to form the thin-film containing one or more chalcogenide compounds containing Cu, In, Ga, and Se.

19. The method of claim 1 wherein processing comprise selenizing without the separate annealing step in an atmosphere containing hydrogen gas, but may be densified and selenized in one step with a ramp-rate of over 5 C/sec, to a temperature of 225 to 575 C for a time period of about 120 seconds to about 20 minutes in an atmosphere containing either H2Se or a mixture of H2 and Se vapor in a non-vacuum pressure.
